(19) United States
(12) Patent Application Publication
(10) Pub. No.: US 2026/0340213 A1
(43) Pub. Date: Oct. 29, 2026

(54) MACHINING LOAD DETERMINATION SYSTEM

(71) Applicant: FANUC CORPORATION, Minamitsuru-gun, Yamanashi (JP)

(72) Inventor: Junichiro KONO, Yamanashi (JP)

(73) Assignee: FANUC CORPORATION, Minamitsuru-gun, Yamanashi (JP)

(21) Appl. No.: 19/111,534

(22) PCT Filed: Nov. 21, 2022
(86) PCT No.: PCT/JP2022/042945

§ 371 Date: Mar. 13, 2025

(51) Int. Cl. G06F 30/17

(52) U.S. Cl. CPC G06F 30/17

(57) ABSTRACT

This invention provides a system which increases a detection precision of a difference between simulation and actual machining without limiting a precision of the simulation. This machining load determination system comprises: an actual machining unit which includes a movable unit provided with a tool or a workpiece; a simulation unit which has a virtual space including a virtual tool, a virtual workpiece, and a virtual movable unit; a virtual load acquisition unit which acquires information relating to a virtual load occurring to the virtual movable unit; an actual load acquisition unit which acquires information relating to an actual load occurring to the movable unit; and a load information determination unit which determines whether or not a difference exists between the virtual load information and the actual load information. The simulation unit calculates the virtual load information and comparison position specification data which specifies a position for comparing the virtual load information and the actual load information with each other. The virtual load acquisition unit acquires the virtual load information in association with the comparison position specification data. The actual load acquisition unit acquires the actual load information in association with the comparison position specification data. The load information determination unit compares the virtual load information and the actual load information with each other on the basis of the comparison position specification data.

### TECHNICAL FIELD

The present invention relates to a machining load determination system.

### BACKGROUND ART

There are industrial machines each of which includes a movable unit provided with a tool or a machining target object and machines the machining target object by relatively moving the tool and the machining target object (for example, a machine tool and an electric spark machine). For such industrial machines, a technology is known in which machining simulation is performed in a virtual space as a three-dimensional model obtained by recreating an environment similar to an environment where actual machining is to be performed, and whether or not there is a problem in operation data (for example, a machining program) is checked.

In such a technology, there may be cases where an unintentional difference arises between the three-dimensional model of the virtual space defined for simulation and the actual environment due to various factors. The various factors may include, for example, that the machining target object is lifted during machining in the actual environment and that wear compensation of the tool is forgotten to be reflected in the three-dimensional model of the virtual space. In this case, a difference may arise between a result obtained by way of simulation and a result obtained in actual machining.

In this respect, Patent Document 1 discloses a technique in which an actual machine unit and a simulation unit are arranged in parallel, the same command is input to the actual machine unit and the simulation unit, a comparison is made between internal state quantities of the actual machine unit and the simulation unit, and an internal state quantity comparison value is compared with a preset detection threshold, thereby detecting contact/collision of a movable unit with another object. This technique is considered to enable detection of whether or not there is a difference between a result obtained by way of simulation and a result obtained in actual machining. Further, Patent Document 1 discloses that arithmetic expressions of a model of the simulation unit is simple, and the processing time is short.

### CITATION LIST

### Patent Document

Patent Document 1: Japanese Unexamined Patent Application, Publication No. 2004-364396

### DISCLOSURE OF THE INVENTION

### Problems to be Solved by the Invention

According to the technique disclosed in Patent Document 1, it is necessary to make the simulation unit perform simulation in accordance with operation of the actual machine unit in real time. Processing time of simulation using a three-dimensional model as virtual space is relatively long. For this reason, in the technique disclosed in Patent Document 1, the arithmetic expressions of the model of the simulation unit are simplified to shorten the processing time in accordance with operation time of the actual machine unit.

Thus, in real-time simulation for actual machining, the accuracy of the simulation is limited. As a result, there may be cases where it is not possible to correctly detect a difference between simulation and actual machining. Therefore, it is desired to enhance the accuracy of detection of a difference between simulation and actual machining without limiting the accuracy of the simulation.

### Means for Solving the Problems

A machining load determination system of the present disclosure includes: an actual machining unit that includes a movable unit provided with a tool or a machining target object and machines the machining target object by relatively moving the tool and the machining target object based on operation data; a simulation unit that performs, in a virtual space including a virtual tool, a virtual machining target object, and a virtual movable unit corresponding to the tool, the machining target object, and the movable unit, respectively, machining simulation of machining the virtual machining target object by relatively moving the virtual tool and the virtual machining target object based on the operation data; a virtual load acquisition unit that acquires virtual load information, which is information about a virtual load that occurs on the virtual movable unit, the virtual load information having been obtained by way of the machining simulation by the simulation unit; an actual load acquisition unit that acquires actual load information, which is information about an actual load that occurs on the movable unit, the actual load information having been obtained by way of the machining by the actual machining unit; and a load information determination unit that makes determination as to whether or not there is a difference between the virtual load information and the actual load information by comparing the virtual load information with the actual load information. The simulation unit calculates the virtual load information, and comparison position identification data identifying a position of comparison between the virtual load information and the actual load information; the virtual load acquisition unit acquires the virtual load information in association with the comparison position identification data; the actual load acquisition unit acquires the actual load information in association with the comparison position identification data; and the load information determination unit compares the virtual load information with the actual load information based on the comparison position identification data.

### BRIEF DESCRIPTION OF THE DRAWINGS

FIG. 1 is a diagram showing an overview of an industrial machine system according to a present embodiment;

FIG. 2 is a diagram showing a configuration of a machining load determination system according to the present embodiment;

FIG. 3A is a diagram showing an example of virtual load information and comparison position identification data;

FIG. 3B is a diagram showing an example of actual load information and comparison position identification data;

FIG. 4A is a diagram showing an example 1 of machining load determination processing by the machining load determination system according to the present embodiment (in a case where there is no difference between an actual machining unit and a simulation unit);

FIG. 4B is a diagram showing the example 1 of the machining load determination processing by the machining load determination system according to the present embodiment (in a case where there is a difference between the actual machining unit and the simulation unit: a pattern in which contact is detected only by the simulation unit);

FIG. 4C is a diagram showing the example 1 of the machining load determination processing by the machining load determination system according to the present embodiment (in the case where there is a difference between the actual machining unit and the simulation unit: a pattern in which contact is detected only by the actual machining unit);

FIG. 4D is a diagram showing the example 1 of the machining load determination processing by the machining load determination system according to the present embodiment (in the case where there is a difference between the actual machining unit and the simulation unit: a pattern in which lifting of a workpiece occurs);

FIG. 5A is a diagram showing an example 2 of the machining load determination processing by the machining load determination system according to the present embodiment (in the case where there is no difference between the actual machining unit and the simulation unit);

FIG. 5B is a diagram showing the example 2 of the machining load determination processing by the machining load determination system according to the present embodiment (in the case where there is a difference between the actual machining unit and the simulation unit: the pattern in which contact is detected only by the simulation unit);

FIG. 5C is a diagram showing the example 2 of the machining load determination processing by the machining load determination system according to the present embodiment (in the case where there is a difference between the actual machining unit and the simulation unit: the pattern in which contact is detected only by the actual machining unit);

FIG. 6A is a diagram showing an example 3 of the machining load determination processing by the machining load determination system according to the present embodiment (in the case where there is no difference between the actual machining unit and the simulation unit);

FIG. 6B is a diagram showing the example 3 of the machining load determination processing by the machining load determination system according to the present embodiment (in the case where there is a difference between the actual machining unit and the simulation unit: the pattern in which contact is detected only by the simulation unit);

FIG. 6C is a diagram showing the example 3 of the machining load determination processing by the machining load determination system according to the present embodiment (in the case where there is a difference between the actual machining unit and the simulation unit: the pattern in which contact is detected only by the actual machining unit);

FIG. 7 is a diagram showing an example 4 of the machining load determination processing by the machining load determination system according to the present embodiment; and

FIG. 8 is a diagram showing an example 5 of the machining load determination processing by the machining load determination system according to the present embodiment.

### PREFERRED MODE FOR CARRYING OUT THE INVENTION

An example of the present embodiment will be described below with reference to accompanying drawings. Note that the same or corresponding portions in the drawings will be given the same reference numeral.

### [Overview of Industrial Machine System]

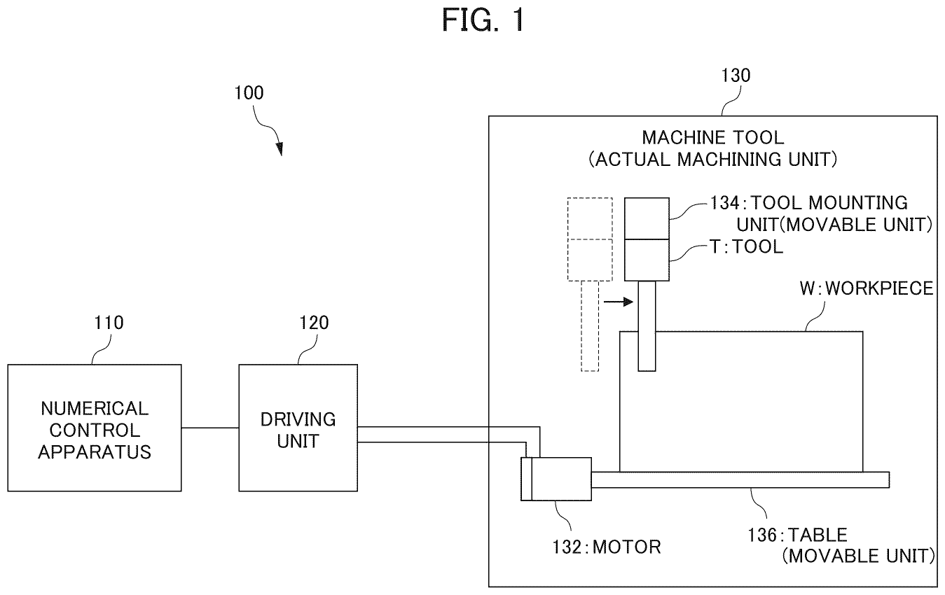

First, an overview of an industrial machine system according to the present embodiment will be described. FIG. 1 is a diagram showing an overview of the industrial machine system according to the present embodiment. As shown in FIG. 1, an industrial machine system 100 includes a numerical control apparatus 110, a driving unit 120, and a machine tool (an industrial machine) 130.

The machine tool 130 is an actual machining unit to be described later, and it performs removal processing of a workpiece (machining target object) W by relatively moving a tool T and the workpiece W based on operation data. Though an M-series (Machining Center Series) machine will be exemplified as the machine tool below, the present embodiment is not limited thereto. The present embodiment is also applicable to a T-series (lathe series) machine tool. Further, though the machine tool is exemplified as an industrial machine, the present embodiment is not limited thereto. The present embodiment is also applicable to various industrial machines in which machining of the workpiece W is performed by the tool T and the workpiece W coming into contact with each other, for example, an electric spark machine.

The machine tool 130 includes a motor 132, a tool mounting unit 134, and a table 136. The mounting unit 134 or the table 136 is a movable unit. The tool T is mounted on the mounting unit 134, and the workpiece W is provided on the table 136.

The motor 132 is a motor for feeding the movable unit such as the mounting unit 134 or the table 136, that is, the tool T or the workpiece W, and may include a plurality of motors, for example, for X-axis movement, Y-axis movement, and Z-axis movement. The motor 132 is driven by the driving unit 120.

The numerical control apparatus 110 generates a position command along a relative movement route of the tool T relative to the workpiece W in the machine tool 130, based on a machining program.

The driving unit 120 drives the motor 132 in the machine tool 130, based on the position command from the numerical control apparatus 110. The driving unit 120 may include a plurality of driving units for the motors (for example, the X-axis motor, the Y-axis motor, and the Z-axis motor) of the machine tool 130, respectively. The driving unit 120 is, for example, a servo control unit, and performs drive control of the motor 132 based on the position command and position feedback detected by an encoder provided in the motor 132.

### [Machining Load Determination System]

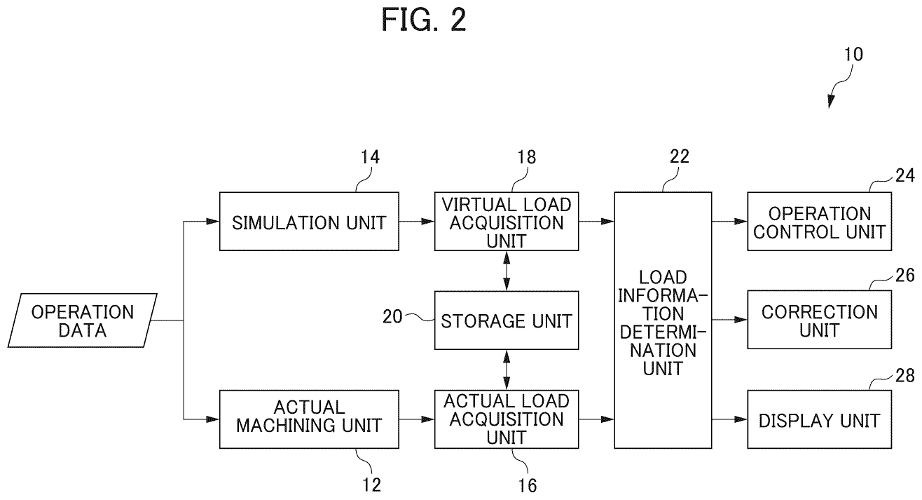

FIG. 2 is a diagram showing a configuration of a machining load determination system according to the present embodiment. As shown in FIG. 2, a machining load determination system 10 includes an actual machining unit 12, a simulation unit 14, an actual load acquisition unit 16, a virtual load acquisition unit 18, a storage unit 20, a load information determination unit 22, an operation control unit 24, a correction unit 26, and a display unit 28.

The actual machining unit 12 is the machine tool 130 described above. As described above, the actual machining unit 12 machines the workpiece W by relatively moving the tool T and the workpiece W based on the operation data, with the mounting unit 134 provided with the tool T or the table 136 provided with the workpiece W as the movable unit.

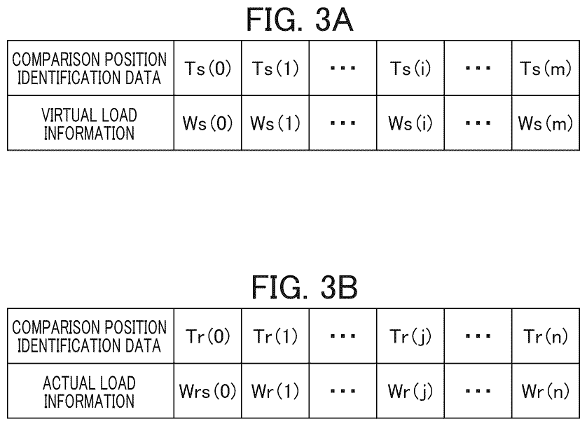

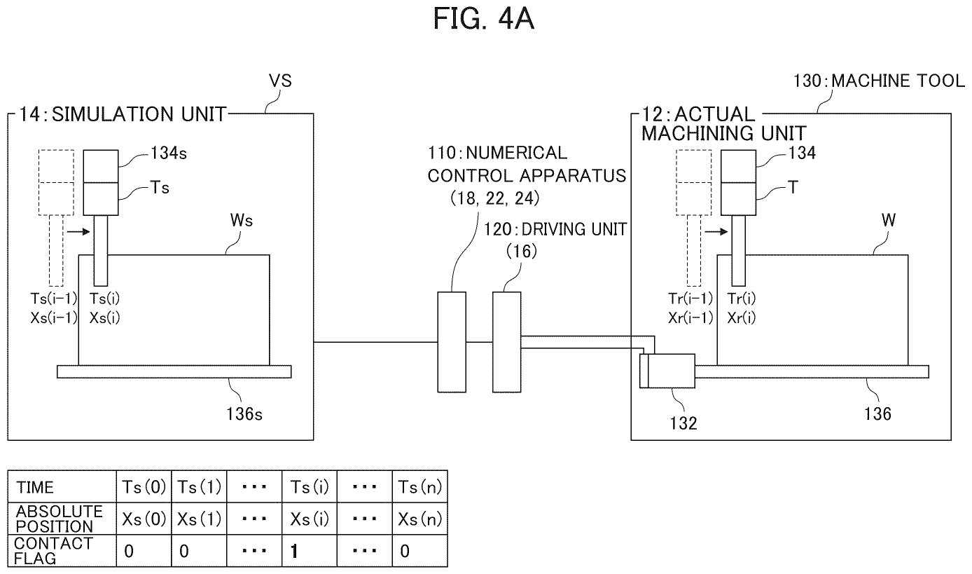

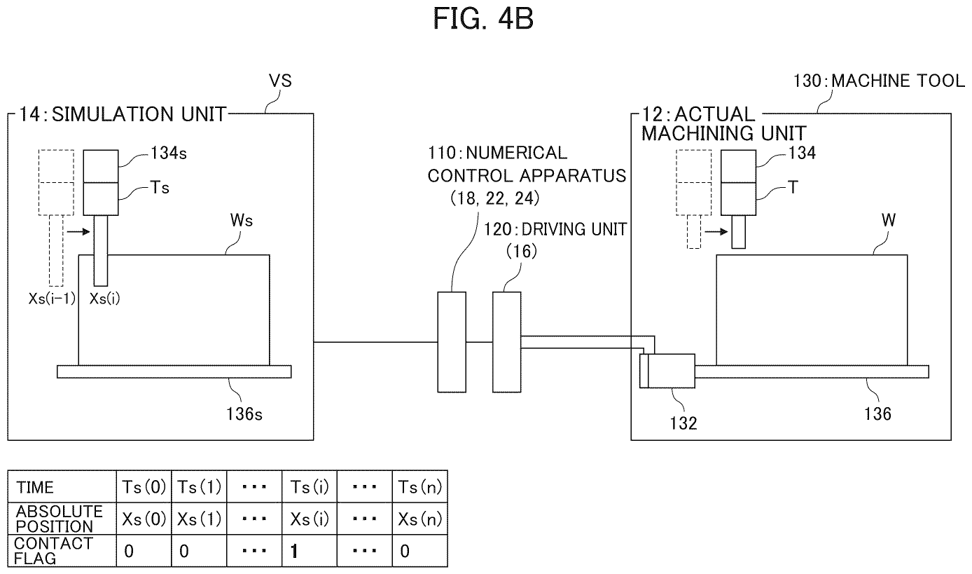

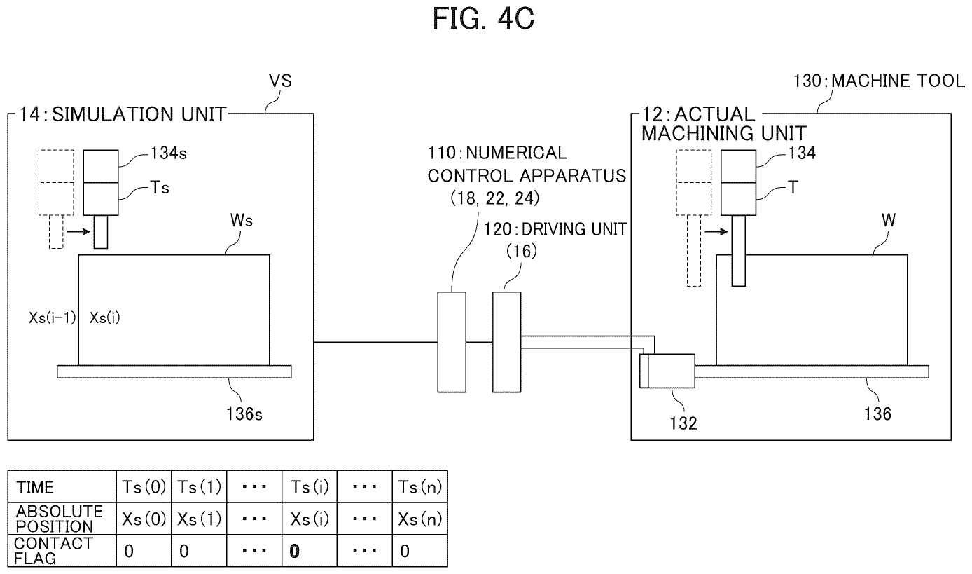

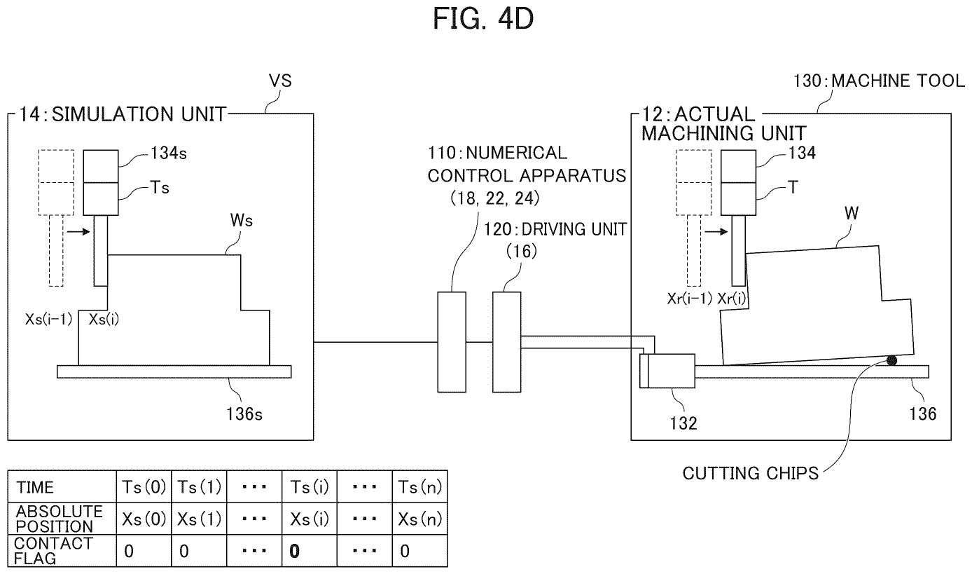

The simulation unit 14 may be provided in the numerical control apparatus 110 described above or may be configured with a computer different from the numerical control apparatus 110. For example, as shown in FIG. 4A to be described later, the simulation unit 14 has virtual space VS that includes a virtual tool Ts, a virtual workpiece Ws, a virtual mounting unit (virtual movable unit) 134s, and a table (virtual movable unit) 136s imitating the tool T, the workpiece W, the mounting unit (movable unit) 134, and the table (movable unit) 136 of the actual machining unit 12, respectively. The simulation unit 14 performs simulation of machining of the virtual workpiece Ws by relatively moving the virtual tool Ts and the virtual workpiece Ws based on operation data in the virtual space VS. As shown in FIG. 3A, the simulation unit 14 calculates information about a virtual load that occurs on the virtual movable unit 134s or 136s, and comparison position identification data identifying a position of comparison between the virtual load information and actual load information. Details of the virtual load information and the comparison position identification data will be described later.

The actual load acquisition unit 16 is provided in the driving unit (servo control unit) 120 described above. As shown in FIG. 3B, the actual load acquisition unit 16 acquires information about an actual load that occurs on the movable unit 134 or 136, which has been obtained by way of machining by the actual machining unit 12. Specifically, the actual load acquisition unit 16 acquires the virtual load information in association with the comparison position identification data. Details of the actual load information and the comparison position identification data will be described later.

The virtual load acquisition unit 18 may be provided in the numerical control apparatus 110 described above, may be provided in a computer constituting the simulation unit 14, or may be configured with a computer different from the numerical control apparatus 110 and the simulation unit 14. As shown in FIG. 3A, the virtual load acquisition unit 18 acquires the information about the virtual load that occurs on the virtual movable unit 134s or 136s, which has been obtained by way of machining simulation by the simulation unit 14. Specifically, the virtual load acquisition unit 18 acquires the virtual load information in association with the comparison position identification data.

The load information determination unit 22 may be provided in the numerical control apparatus 110 described above, may be provided in the driving unit (servo control unit) 120, or may be configured with a computer different from the numerical control apparatus 110 and the driving unit 120. The load information determination unit 22 compares the virtual load information with the actual load information based on the comparison position identification data to determine whether or not there is a difference between the pieces of information. That is, the load information determination unit 22 determines whether or not there is a difference between the load information about the movable unit 134 or 136 of the actual machining unit 12 and the load information about the virtual movable unit 134s or 136s of the simulation unit 14.

The operation control unit 24 is provided in the driving unit (servo control unit) 130 described above. In a case where the load information determination unit 22 determines that there is a difference between the virtual load information and the actual load information, the operation control unit 24 performs at least any of restriction of output for causing the movable unit 134 or 136 to operate (for example, torque restriction), retraction operation of the movable unit 134 or 136 preset in the machining program, or immediate decelerating and stopping of operation of the movable unit 134 or 136, in the actual machining unit 12.

The correction unit 26 may be provided in the numerical control apparatus 110 described above or may be configured with a computer different from the numerical control apparatus 110. In a case where the load information determination unit 22 determines that there is a difference between the virtual load information and the actual load information, the correction unit 26 changes (corrects) prerequisites for machining simulation, for example, prerequisites about the virtual tool Ts, the virtual workpiece Ws, and the virtual movable unit 134s or 136s in the operation data, in the simulation unit 14.

The simulation unit 14, the actual load acquisition unit 16, the virtual load acquisition unit 18, the load information determination unit 22, the operation control unit 24, and the correction unit 26 are configured with an arithmetic processor, for example, a CPU (Central Processing Unit), a DSP (Digital Signal Processor), an FPGA (Field-Programmable Gate Array), or the like. Various functions of the simulation unit 14, the actual load acquisition unit 16, the virtual load acquisition unit 18, the load information determination unit 22, the operation control unit 24, and the correction unit 26 are realized, for example, by executing predetermined software (program) stored in the storage unit 20. The various functions of the simulation unit 14, the actual load acquisition unit 16, the virtual load acquisition unit 18, the load information determination unit 22, the operation control unit 24, and the correction unit 26 may be realized by cooperation between hardware and software or may be realized only by hardware (electronic circuits).

The storage unit 20 is configured with a memory, for example, a ROM (Read Only Memory), an HDD (Hard Disk Drive), an SSD (Solid State Drive), or the like. The storage unit 20 stores the predetermined software (program) that realizes the various functions of the simulation unit 14, the actual load acquisition unit 16, the virtual load acquisition unit 18, the load information determination unit 22, the operation control unit 24, and the correction unit 26. Further, the storage unit 20 stores the virtual load information and the comparison position identification data acquired by the virtual load acquisition unit 18, which is shown in FIG. 3A, and the actual load information and the comparison position identification data acquired by the actual load acquisition unit 16, which is shown in FIG. 3B.

The display unit 28 is configured, for example, with a liquid crystal display or an organic EL display. The display unit 28 displays comparison position identification data for which it has been determined by the load information determination unit 22 that there is a difference between the virtual load information and the actual load information, in a manner varying according to the difference. For example, in the program (operation data), the display unit 28 highlights and displays blocks corresponding to pieces of comparison position identification data for which it is determined that there is a difference between the virtual load information and the actual load information, in a display manner (for example, color and blinks) different from that of blocks without a difference.

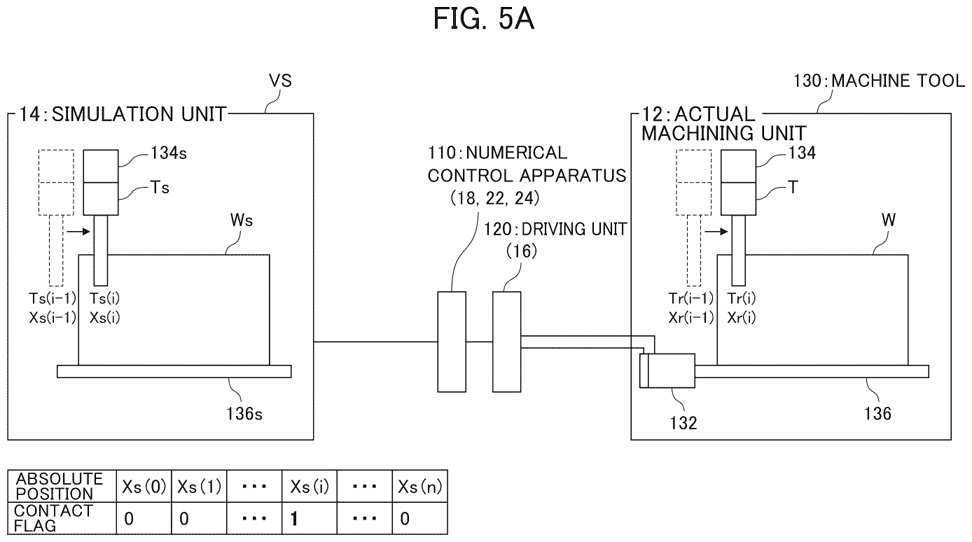

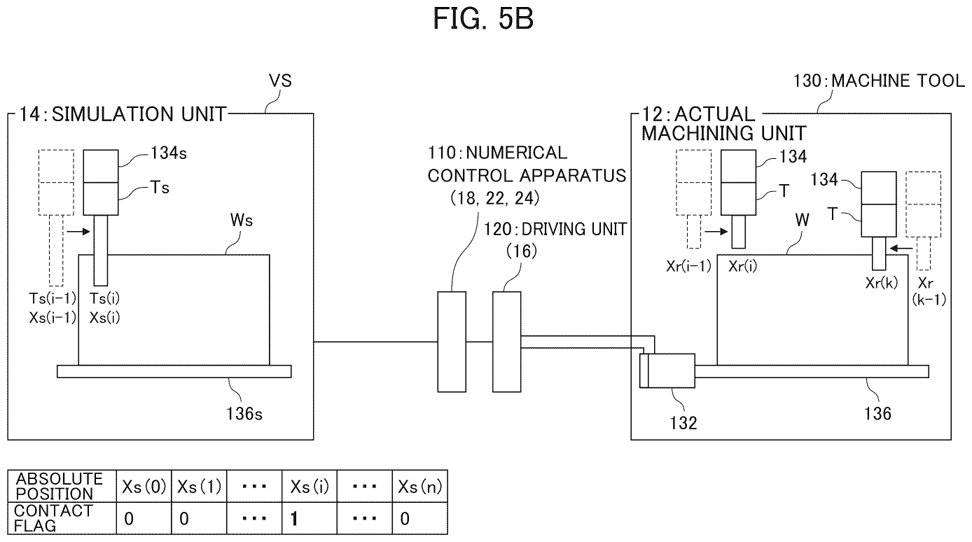

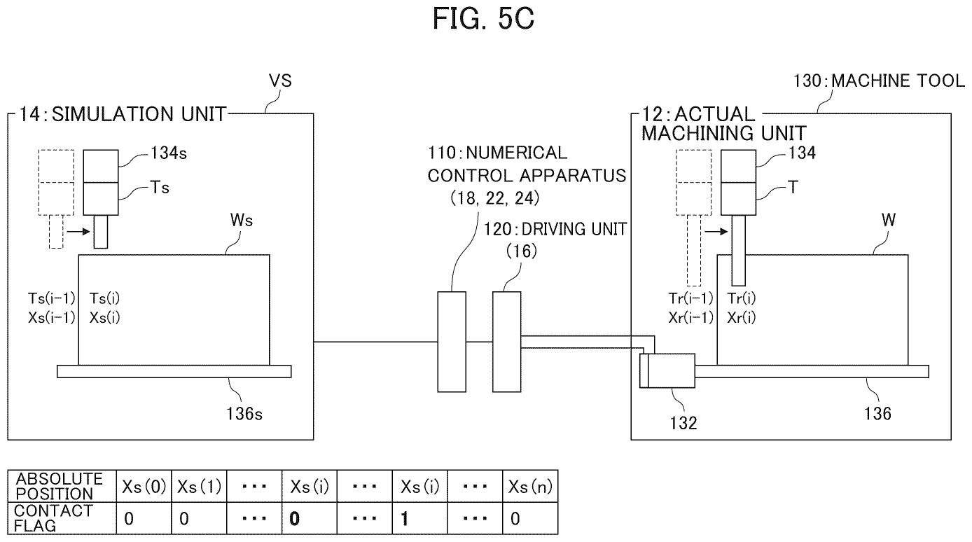

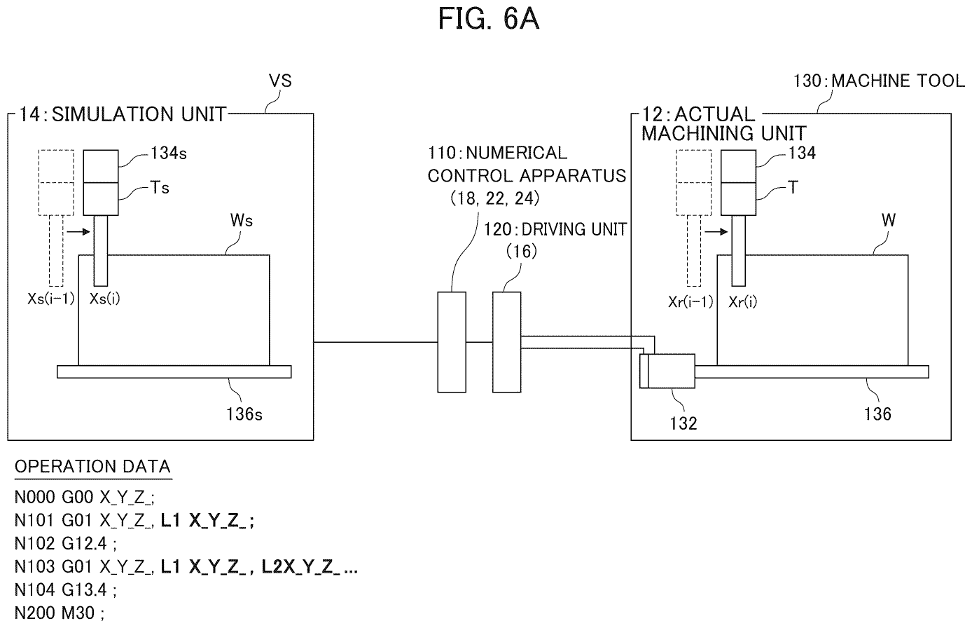

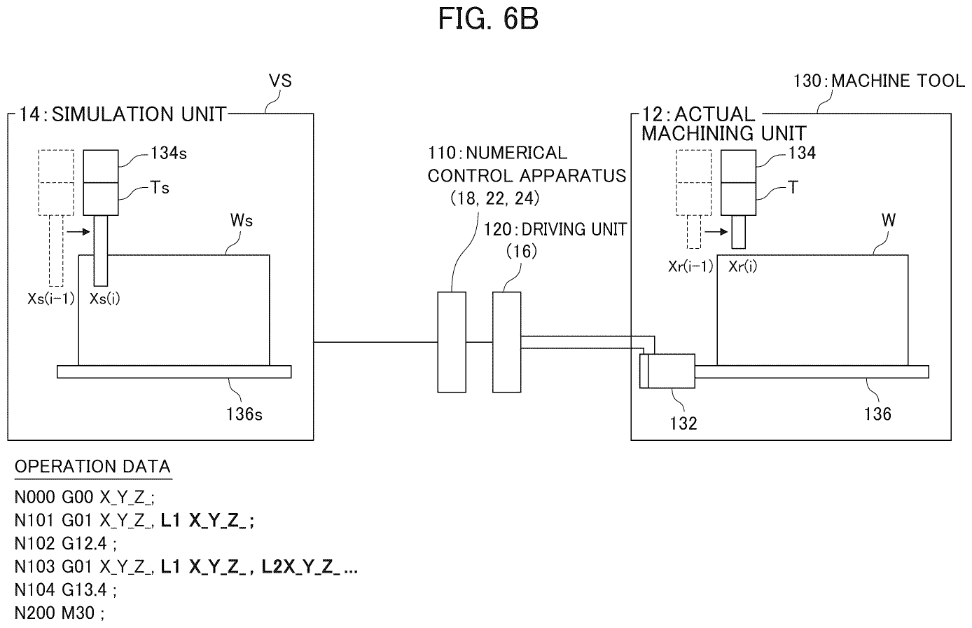

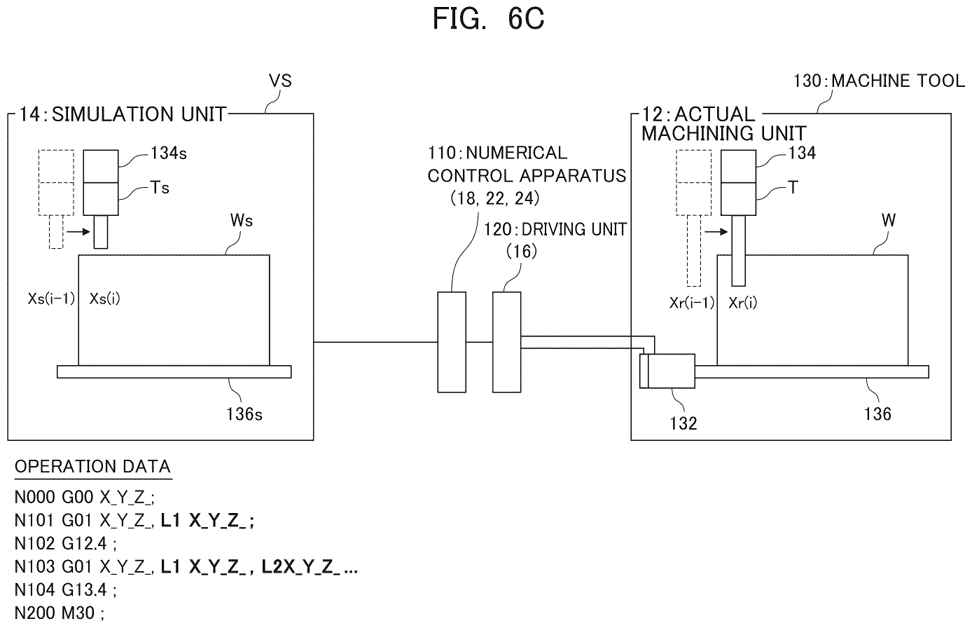

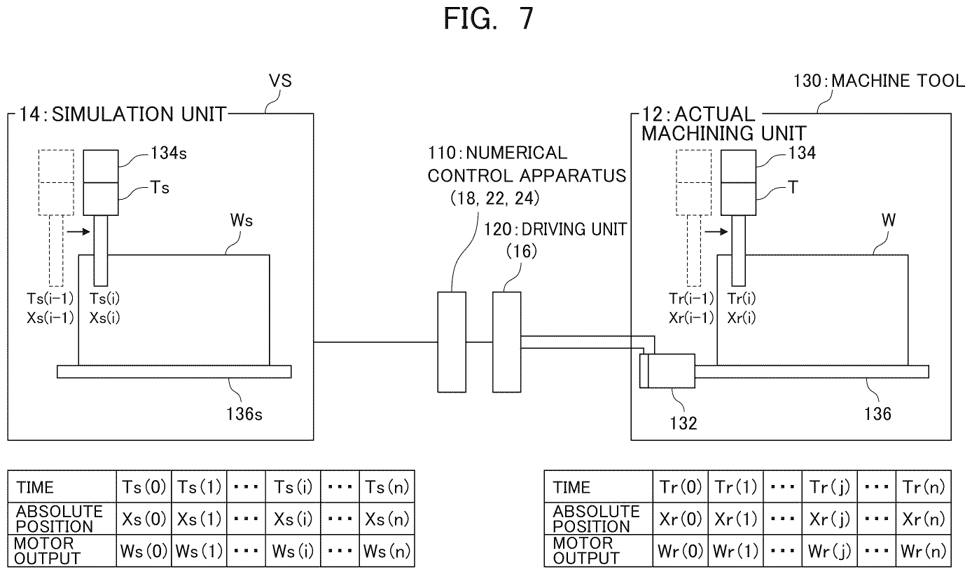

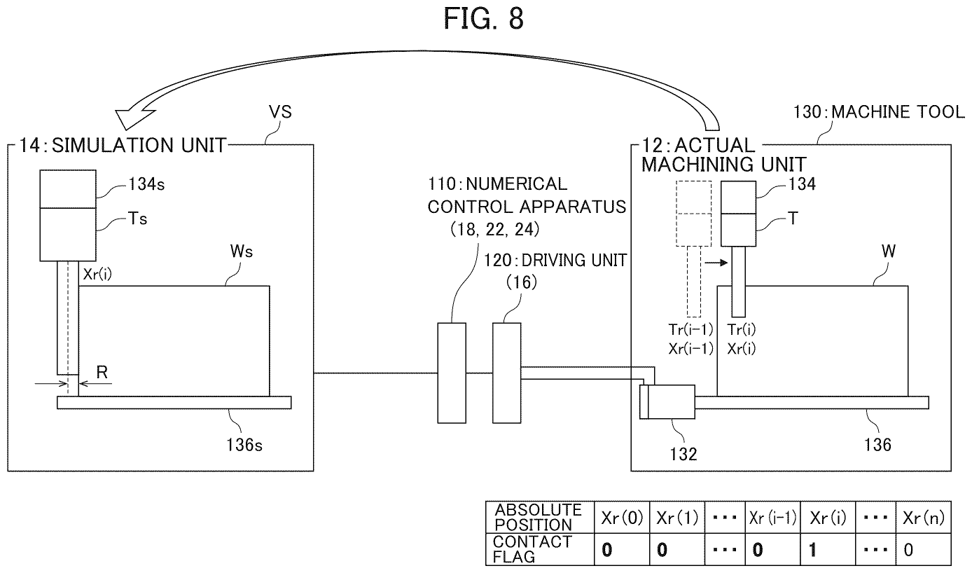

Next, a description will be made on some examples of machining load determination processing by the machining load determination system 10 described above with reference to FIGS. 4A to 8. FIGS. 4A to 4D are diagrams showing an example 1 of the machining load determination processing by the machining load determination system according to the present embodiment; FIGS. 5A to 5D are diagrams showing an example 2 of the machining load determination processing by the machining load determination system according to the present embodiment; and FIGS. 6A to 6C are diagrams showing an example 3 of the machining load determination processing by the machining load determination system according to the present embodiment. FIG. 7 is a diagram showing an example 4 of the machining load determination processing by the machining load determination system according to the present embodiment; and FIG. 8 is a diagram showing an example 5 of the machining load determination processing by the machining load determination system according to the present embodiment.

### Example 1

In the example 1, elapsed time of operation of the program (time information) is used as the comparison position identification data. FIG. 4A is a diagram showing a case where there is no difference between the actual load information about the movable unit of the actual machining unit and the virtual load information about the virtual movable unit of the simulation unit; and FIG. 4B is a diagram showing a case where there is a difference between the actual load information about the movable unit of the actual machining unit and the virtual load information about the virtual movable unit of the simulation unit (a pattern in which contact is detected only by the simulation unit). FIG. 4C is a diagram showing a case where there is a difference between the actual load information about the movable unit of the actual machining unit and the virtual load information about the virtual movable unit of the simulation unit (a pattern in which contact is detected only by the actual machining unit); and FIG. 4D is a diagram showing a case where there is a difference between the actual load information about the movable unit of the actual machining unit and the virtual load information about the virtual movable unit of the simulation unit (a pattern in which lifting of the workpiece occurs).

(Case where there is No Difference Between Actual Machining Unit and Simulation Unit)
<1-1>

As shown in FIG. 4A, for example, the numerical control apparatus 110 analyzes the machining program, creates time-series data Xs(0), Xs(1), . . . , Xs(n) of machine coordinates Xs(i) of the virtual movable unit 134s or 136s after time Ts(i) seconds from start time Ts(0), as the operation data for the simulation unit 14, and outputs the time-series data Xs(0), Xs(1), . . . , Xs(n) to the simulation unit 14. Further, for example, the numerical control apparatus 110 analyzes the machining program, creates time-series data Xr(0), Xr(1), . . . , Xr(n) of machine coordinates Xr(j) of the movable unit 134 or 136 after time Tr(j) seconds from start time Tr(0), as the operation data for the actual machining unit 12, and outputs the time-series data Xr(0), Xr(1), . . . , Xr(n) to the driving unit 120. Here, i and j are arbitrary integers between 1 and n. n is an integer equal to or larger than 1. Further, Xs(i) and Xr(j) are q-dimensional arrays, and machine coordinates of the p-th axis of the virtual movable unit and machine coordinates of the p-th axis of the movable unit can be represented by Xsp(i) and Xrp(j), respectively. Here, q is an integer equal to or larger than 1 and represents the number of axes of the machine. p is an arbitrary integer between 1 and q.

In the present embodiment, the form of the numerical control apparatus 110 analyzing the machining program and creating the time-series data of machine coordinates (operation data) is exemplified. The present embodiment, however, is not limited thereto, and the computer constituting the simulation unit 14 or another computer may analyze the machining program and create the time-series data of machine coordinates (operation data).

<1-2>

The simulation unit 14 performs simulation of machining of the virtual workpiece Ws by relatively moving the virtual tool Ts and the virtual workpiece Ws based on the machine coordinates Xs(0), . . . , Xs(n) (operation data) output from the numerical control apparatus 110.

The simulation unit 14 calculates contact information indicating whether or not the virtual tool Ts and the virtual workpiece Ws are in contact with each other, as information about a virtual load that occurs on the virtual movable unit 134s or 136s, at certain machine coordinates Xs(i) at certain time Ts(i). For example, the simulation unit 14 sets a contact flag to 0 when the virtual tool Ts is outside the virtual workpiece Ws, and sets the contact flag to 1 when the virtual tool Ts moves from the outside to the inside of the virtual workpiece Ws.

Further, the simulation unit 14 calculates the certain time Ts(i) as comparison position identification data that identifies a position of comparison between the virtual load information and the actual load information. Specifically, the pieces of comparison position identification data are data that associate time-series or machining positions between the virtual load information and the actual load information. More specifically, the pieces of comparison position identification data are data that cause the time Ts(i) when the virtual tool Ts and the virtual workpiece Ws come into contact with each other in the simulation unit 14 and the time Tr(j) when the tool T and the workpiece W come into contact with each other in the actual machining unit 12 to correspond to each other one-to-one. That is, the pieces of comparison position identification data are data that identify the time Ts(i) and the time Tr(j) as positions of comparison between the virtual load information and the actual load information. Thereby, the load information determination unit 22 can appropriately compare the virtual load information at the time Ts(i) with the actual load information at the time Tr(j) based on the pieces of comparison position identification data. As described above, the simulation unit 14 may be provided in the numerical control apparatus 110 or may be configured with a computer different from the numerical control apparatus 110.

As shown in FIG. 4A, the numerical control apparatus 110 (the virtual load acquisition unit 18) acquires the contact flag 0/1 (virtual load information) in association with the time Ts(i) (comparison position identification data).

The simulation unit 14 performs the machining simulation described above before the actual machining unit 12 operates based on the operation data, and calculates the virtual load information and the comparison position data in advance.

Further, the virtual load acquisition unit 18 may acquire the virtual load information in association with the comparison position identification data in advance before the actual machining unit 12 operates based on the operation data and temporarily store the virtual load information and the comparison position identification data in the storage unit 20.

<1-3>

The driving unit 120 drives the motor 132 and the movable unit 134 or 136 of the actual machining unit 12 based on the machine coordinates Xr(0), . . . , Xr(n) (operation data) output from the numerical control apparatus 110. Thereby, the actual machining unit 12 machines the workpiece W by relatively moving the tool T and the workpiece W.

The driving unit 120 (the actual load acquisition unit 16) acquires contact information indicating whether or not the tool T and the workpiece W are in contact with each other, as information about a load that occurs on the movable unit 134 or 136, at certain machine coordinates Xr(j) at certain time Tr(j). For example, the driving unit 120 (the actual load acquisition unit 16) monitors output of the motor 132 (commands or feedback information), determines that the tool T and the workpiece W have come into contact with each other when the output of the motor 132 exceeds a certain threshold, and outputs a contact signal to the numerical control apparatus 110.

The driving unit 120 (the actual load acquisition unit 16) acquires the contact signal (actual load information) in association with the time Tr(j) (comparison position identification data).

<1-4>

The numerical control apparatus 110 (the load information determination unit 22) compares the contact signal (actual load information) with the contact flag (virtual load information) based on the time Tr(j) and Ts(i) (comparison position identification data) and determines whether or not there is a difference between the pieces of information. For example, in FIG. 4A, the numerical control apparatus 110 (the load information determination unit 22) acquires the contact signal (actual load information) between the time Ts(i−1) and Ts(i) based on the time Tr(j) and Ts(i) (comparison position identification data), and determines that there is no difference between the pieces of information because the contact flag (virtual load information) then is 1.

The load information determination unit 22 performs the determination described above in real time while the actual machining unit 12 is operating, based on the virtual load information obtained by the simulation unit 14 in advance and the actual load information obtained by the actual machining unit 12 in real time. The load information determination unit 22 may extract only virtual load information and actual load information in a certain particular section in the pieces of comparison position identification data and compare the virtual load information with the actual load information.

When there is no difference between the actual load information and the virtual load information, the numerical control apparatus 110 (the operation control unit 24) does not restrict operation.

As described above, the load information determination unit 22 may be provided in the numerical control apparatus 110, may be provided in the driving unit 120 (a servo control unit or an amplifier), or may be configured with a computer different from the numerical control apparatus 110 and the driving unit 120.

When the load information determination unit 22 is provided in the driving unit 120 (a servo control unit or an amplifier), the load information determination unit 22 may calculate the time Tr(j) when the contact signal has been detected in the actual machining unit 12, on the driving unit 120 side, and determine that there is no difference between the actual load information and the virtual load information if the time Tr(j) and the time Ts(i−1) and Ts(i) when the contact flag changes from 0 to 1 in the simulation unit 14 satisfy the following equality. Ts(i−1)≤Tr(j)≤Ts(i)

Since the cycle of acquiring the position of the movable unit in the actual machining unit is generally shorter than a simulation cycle, an error (delay time) of the time Tr(j) when the contact signal has been detected in the actual machining unit 12 can be ignored. When the error (delay time) of the actual machining unit is smaller than an error of the simulation unit 14, however, the load information determination unit 22 may determine that there is no difference between the actual load information and the virtual load information if the time Ts(i) when the contact flag becomes 1 in the simulation unit 14 exists between the time Tr(j−1) and Tr(j) in the actual machining unit 12.

Further, in addition to the determination by the contact time described above, the load information determination unit 22 may determine that there is no difference between the actual load information and the virtual load information further based on a determination by a contact position as described below. For example, the load information determination unit 22 may furthermore determine that there is no difference between the actual load information and the virtual load information when the machine coordinates Xr(j) when the contact signal has been detected in the actual machining unit 12 and machine coordinates Xs(i−1) and Xs(i) when the contact flag changes from 0 to 1 in the simulation unit 14 satisfy the following equality for all axes p operating between i−1 and i.

|Xrp(j)−Xsp(i)|≤|Xsp(i)−Xsp(i−1)|

Thereby, it is possible to exclude a case where contact times (collision times) happen to correspond as a result of a series of mistakes.
(Case where there is difference between actual machining unit and simulation unit) (pattern in which contact is detected only by simulation unit)
<1-1>

As shown in FIG. 4B, for example, the numerical control apparatus 110 creates the time-series data Xs(0), Xs(1), . . . , Xs(n) of the machine coordinates Xs(i) of the virtual movable unit 134s or 136s after time Ts(i) seconds from the start time Ts(0), as the operation data for the simulation unit 14 similarly to the above. Further, for example, the numerical control apparatus 110 creates the time-series data Xr(0), Xr(1), . . . , Xr(n) of the machine coordinates Xr(j) of the movable unit 134 or 136 after time Tr(j) seconds from the start time Tr(0), as the operation data for the actual machining unit 12 similarly to the above.

<1-2>

Similarly to the above, the simulation unit 14 performs simulation of machining of the virtual workpiece Ws, and, as shown in FIG. 4B, the numerical control apparatus 110 (the virtual load acquisition unit 18) acquires the contact flag 0/1 (virtual load information) in association with the time Ts(i) (comparison position identification data).

<1-3>

Similarly to the above, the driving unit 120 and the actual machining unit 12 machine the workpiece W, and the driving unit 120 (the actual load acquisition unit 16) acquires a contact signal (actual load information) in association with the time Tr(j) (comparison position identification data). For example, in FIG. 4B, the tool T and the workpiece W do not come into contact with each other due to damage or incorrect mounting of the tool, and the driving unit 120 (the actual load acquisition unit 16) does not acquire a contact signal and does not output a contact signal to the numerical control apparatus 110.

<1-4>

Similarly to the above, the numerical control apparatus 110 (the load information determination unit 22) compares the contact signal (actual load information) with the contact flag (virtual load information) based on the time Tr(j) and Ts(i) (comparison position identification data) and determines whether or not there is a difference between the pieces of information. For example, in FIG. 4B, the numerical control apparatus 110 (the load information determination unit 22) does not acquire a contact signal (actual load information) between the time Ts(i−1) and Ts(i), and determines that there is a difference between the pieces of information because the contact flag (virtual load information) then is 1.

When there is a difference between the actual load information and the virtual load information, the numerical control apparatus 110 (the operation control unit 24) decelerates and stops the machine tool 130. The numerical control apparatus 110 (the operation control unit 24) may immediately stop output of the motor or may perform an emergency stop operation specified in advance. That is, the numerical control apparatus 110 (the operation control unit 24) performs restriction of output for causing the movable unit 134 or 136 to operate, a preset retraction operation of the movable unit 134 or 136, or immediate decelerating and stopping of operation of the movable unit 134 or 136, in the actual machining unit 12.

At this time, an operator of the machine tool can recognize incorrect mounting or damage of the tool T by comparing machine coordinates at which contact (interference) has not been detected in actual machining, corresponding to machine coordinates at which contact (interference) has been detected in machining simulation, and machine coordinates at which contact (interference) has been detected in the actual machining.

(Case where there is difference between actual machining unit and simulation unit) (pattern in which contact is detected only by actual machining unit)
<1-1>

As shown in FIG. 4C, for example, the numerical control apparatus 110 creates the time-series data Xs(0), Xs(1), . . . , Xs(n) of the machine coordinates Xs(i) of the virtual movable unit 134s or 136s after time Ts(i) seconds from the start time Ts(0), as the operation data for the simulation unit 14 similarly to the above. Further, for example, the numerical control apparatus 110 creates the time-series data Xr(0), Xr(1), . . . , Xr(n) of the machine coordinates Xr(j) of the movable unit 134 or 136 after time Tr(j) seconds from the start time Tr(0), as the operation data for the actual machining unit 12 similarly to the above.

<1-2>

Similarly to the above, the simulation unit 14 performs simulation of machining of the virtual workpiece Ws, and, as shown in FIG. 4A, the numerical control apparatus 110 (the virtual load acquisition unit 18) acquires the contact flag 0/1 (virtual load information) in association with the time Ts(i) (comparison position identification data). For example, in FIG. 4C, at certain machine coordinates Xs(i) at certain time Ts(i), the virtual tool Ts does not move from the outside to the inside of the virtual workpiece Ws, and the simulation unit 14 sets the contact flag to 0.

<1-3>

Similarly to the above, the driving unit 120 and the actual machining unit 12 machine the workpiece W, and the driving unit 120 (the actual load acquisition unit 16) acquires a contact signal (actual load information) in association with the time Tr(j) (comparison position identification data).

<1-4>

Similarly to the above, the numerical control apparatus 110 (the load information determination unit 22) compares the contact signal (actual load information) with the contact flag (virtual load information) based on the time Tr(j) and Ts(i) (comparison position identification data) and determines whether or not there is a difference between the pieces of information. For example, in FIG. 4B, the numerical control apparatus 110 (the load information determination unit 22) detects a contact signal (actual load information) has been acquired though the contact flag (virtual load information) is not set between the time Ts(i−1) and Ts(i), and determines that there is a difference between the pieces of information.

Similarly to the above, when there is a difference between the actual load information and the virtual load information, the numerical control apparatus 110 (the operation control unit 24) decelerates and stops the machine tool 130.

(Case where there is difference between actual machining unit and simulation unit) (pattern in which lifting of workpiece occurs)
<1-1>

As shown in FIG. 4C, for example, the numerical control apparatus 110 creates the time-series data Xs(0), Xs(1), . . . , Xs(n) of the machine coordinates Xs(i) of the virtual movable unit 134s or 136s after time Ts(i) seconds from the start time Ts(0), as the operation data for the simulation unit 14 similarly to the above. Further, for example, the numerical control apparatus 110 creates the time-series data Xr(0), Xr(1), . . . , Xr(n) of the machine coordinates Xr(j) of the movable unit 134 or 136 after time Tr(j) seconds from the start time Tr(0), as the operation data for the actual machining unit 12 similarly to the above.

<1-2>

Similarly to the above, the simulation unit 14 performs simulation of machining of the virtual workpiece Ws, and, as shown in FIG. 4A, the numerical control apparatus 110 (the virtual load acquisition unit 18) acquires the contact flag 0/1 (virtual load information) in association with the time Ts(i) (comparison position identification data). For example, in FIG. 4D, at certain machine coordinates Xs(i) at certain time Ts(i), the virtual tool Ts does not move from the outside to the inside of the virtual workpiece Ws, and the simulation unit 14 sets the contact flag to 0.

<1-3>

Similarly to the above, the driving unit 120 and the actual machining unit 12 machine the workpiece W, and the driving unit 120 (the actual load acquisition unit 16) acquires a contact signal (actual load information) in association with the time Tr(j) (comparison position identification data). For example, in FIG. 4D, when the workpiece W is lifted from the table 136 due to cutting chips and the like or when the movable unit 134 or 136, or the tool T is lifted, the tool T and the workpiece W come into contact with each other earlier than in simulation, and the driving unit 120 (the actual load acquisition unit 16) outputs a contact signal to the numerical control apparatus 110 earlier than in the simulation. Or alternatively, the tool T and the workpiece W come into contact with each other later than in the simulation, and the driving unit 120 (the actual load acquisition unit 16) outputs a contact signal to the numerical control apparatus 110 later than in the simulation.

<1-4>

Similarly to the above, the numerical control apparatus 110 (the load information determination unit 22) compares the contact signal (actual load information) with the contact flag (virtual load information) based on the time Tr(j) and Ts(i) (comparison position identification data) and determines whether or not there is a difference between the pieces of information. For example, in FIG. 4D, when the tool T and the workpiece W come into contact with each other earlier than in the simulation, the numerical control apparatus 110 (the load information determination unit 22) detects a contact signal (actual load information) has been acquired though the contact flag (virtual load information) is not set between the time Ts(i−1) and Ts(i), and determines that there is a difference between the pieces of information. Or alternatively, when the tool T and the workpiece W come into contact with each other later than in the simulation, the numerical control apparatus 110 (the load information determination unit 22) does not acquire a contact signal (actual load information) between the time Ts(i−1) and Ts(i), and determines that there is a difference between the pieces of information because the contact flag (virtual load information) then is 1.

Similarly to the above, when there is a difference between the actual load information and the virtual load information, the numerical control apparatus 110 (the operation control unit 24) decelerates and stops the machine tool 130.

### Example 2

In the example 2, machine coordinates (position information about the movable units) are used as the pieces of comparison position identification data. Thereby, even when there is a remarkable time (delay) difference between simulation and actual machining due to external factors of the machine tool, it is possible to accurately determine whether or not there is a difference between the actual load information and the virtual load information. FIG. 5A is a diagram showing a case where there is no difference between the actual load information about the movable unit of the actual machining unit and the virtual load information about the virtual movable unit of the simulation unit; and FIG. 5B is a diagram showing a case where there is a difference between the actual load information about the movable unit of the actual machining unit and the virtual load information about the virtual movable unit of the simulation unit (a pattern in which contact is detected only by the simulation unit). FIG. 5C is a diagram showing a case where there is a difference between the actual load information about the movable unit of the actual machining unit and the virtual load information about the virtual movable unit of the simulation unit (a pattern in which contact is detected only by the actual machining unit).

(Case where there is no difference between actual machining unit and simulation unit)
<2-1>

As shown in FIG. 5A, for example, the numerical control apparatus 110 analyzes the machining program, creates time-series data Xs(0), Xs(1), . . . , Xs(n) of the machine coordinates Xs(i) of the virtual movable unit 134s or 136s after time Ts(i) seconds from the start time Ts(0), as the operation data for the simulation unit 14, and outputs the time-series data Xs(0), Xs(1), . . . , Xs(n) to the simulation unit 14. Further, for example, the numerical control apparatus 110 analyzes the machining program, creates time-series data Xr(0), Xr(1), . . . , Xr(n) of the machine coordinates Xr(j) of the movable unit 134 or 136 after time Tr(j) seconds from the start time Tr(0), as the operation data for the actual machining unit 12, and outputs the time-series data Xr(0), Xr(1), . . . , Xr(n) to the driving unit 120. Here, i and j are arbitrary integers between 1 and n. n is an integer equal to or larger than 1.

In the present embodiment, the form of the numerical control apparatus 110 analyzing the machining program and creating the time-series data of machine coordinates (operation data) is exemplified. The present embodiment, however, is not limited thereto, and the computer constituting the simulation unit 14 or another computer may analyze the machining program and create the time-series data of machine coordinates (operation data).

The simulation unit 14 performs simulation of machining of the virtual workpiece Ws by relatively moving the virtual tool Ts and the virtual workpiece Ws based on the machine coordinates Xs(0), . . . , Xs(n) (operation data) output from the numerical control apparatus 110.

The simulation unit 14 calculates contact information indicating whether or not the virtual tool Ts and the virtual workpiece Ws are in contact with each other, as information about a virtual load that occurs on the virtual movable unit 134s or 136s, at certain machine coordinates Xs(i) at certain time Ts(i). For example, the simulation unit 14 sets the contact flag to 0 when the virtual tool Ts is outside the virtual workpiece Ws, and sets the contact flag to 1 when the virtual tool Ts moves from the outside to the inside of the virtual workpiece Ws.

Further, the simulation unit 14 calculates the certain machine coordinates Xs(i) at the certain time Ts(i) as comparison position identification data that identifies a position of comparison between the virtual load information and the actual load information. Specifically, the pieces of comparison position identification data are data that associate time-series or machining positions between the virtual load information and the actual load information. More specifically, the pieces of comparison position identification data are data that cause the machine coordinates Xs(i) at which the virtual tool Ts and the virtual workpiece Ws come into contact with each other in the simulation unit 14 and the machine coordinates Xr(j) at which the tool T and the workpiece W come into contact with each other in the actual machining unit 12 to correspond to each other one-to-one. That is, the pieces of comparison position identification data are data that identify the machine coordinates Xs(i) and the machine coordinates Xr(j) as positions of comparison between the virtual load information and the actual load information. Thereby, the load information determination unit 22 can appropriately compare the virtual load information at the machine coordinates Xs(i) with the actual load information at the machine coordinates Xr(j) based on the pieces of comparison position identification data. As described above, the simulation unit 14 may be provided in the numerical control apparatus 110 or may be configured with a computer different from the numerical control apparatus 110.

As shown in FIG. 5A, the numerical control apparatus 110 (the virtual load acquisition unit 18) acquires the contact flag 0/1 (virtual load information) in association with the machine coordinates Xs(i) (comparison position identification data).

The simulation unit 14 performs the machining simulation described above before the actual machining unit 12 operates based on the operation data, and calculates the virtual load information and the comparison position data in advance. Further, the virtual load acquisition unit 18 may acquire the virtual load information in association with the comparison position identification data in advance before the actual machining unit 12 operates based on the operation data and temporarily store the virtual load information and the comparison position identification data in the storage unit 20.

<2-3>

The driving unit 120 drives the motor 132 and the movable unit 134 or 136 of the actual machining unit 12 based on the machine coordinates Xr(0), . . . , Xr(n) (operation data) output from the numerical control apparatus 110. Thereby, the actual machining unit 12 machines the workpiece W by relatively moving the tool T and the workpiece W.

The driving unit 120 (the actual load acquisition unit 16) acquires contact information indicating whether or not the tool T and the workpiece W are in contact with each other, as information about a load that occurs on the movable unit 134 or 136, at certain machine coordinates Xr(j) at certain time Tr(j). For example, the driving unit 120 (the actual load acquisition unit 16) monitors output of the motor 132 (commands or feedback information), determines that the tool T and the workpiece W have come into contact with each other when the output of the motor 132 exceeds a certain threshold, and outputs a contact signal to the numerical control apparatus 110.

The driving unit 120 (the actual load acquisition unit 16) acquires the contact signal (actual load information) in association with the machine coordinates Xr(j) (comparison position identification data).

<2-4>

The numerical control apparatus 110 (the load information determination unit 22) compares the contact signal (actual load information) with the contact flag (virtual load information) based on the machine coordinates Xr(j) and Xs(i) (comparison position identification data) and determines whether or not there is a difference between the pieces of information. For example, in FIG. 5A, the numerical control apparatus 110 (the load information determination unit 22) determines that there is no difference between the actual load information and the virtual load information based on the machine coordinates Xr(j) and Xs(i) (comparison position identification data), because the machine coordinates Xr(j) (comparison position identification data) at which the contact signal (actual load information) has been detected in the actual machining unit 12 and the machine coordinates Xs(i−1) and Xs(i) (comparison position identification data) at which the contact flag (virtual load information) changes from 0 to 1 in the simulation unit 14 satisfy the following inequality for all the axes p that operate between i−1 to i.

|Xrp(j)−Xsp(i)|≤|Xsp(i)−Xsp(i−1)|

When there are a plurality of pairs of machine coordinates Xr(j) (comparison position identification data) at which a contact signal (actual load information) has been detected in the actual machining unit 12 and a plurality of pairs of machine coordinates Xs(i) (comparison position identification data) at which the contact flag (virtual load information) changes from 0 to 1 in the simulation unit 14, the above determination may be performed in order of contact.

The load information determination unit 22 performs the determination described above in real time while the actual machining unit 12 is operating, based on the virtual load information obtained by the simulation unit 14 in advance and the actual load information obtained by the actual machining unit 12 in real time. The load information determination unit 22 may extract only virtual load information and actual load information in a certain particular section in the pieces of comparison position identification data and compare the virtual load information with the actual load information.

When there is no difference between the actual load information and the virtual load information, the numerical control apparatus 110 (the operation control unit 24) does not restrict operation.

As described above, the load information determination unit 22 may be provided in the numerical control apparatus 110, may be provided in the driving unit 120 (a servo control unit or an amplifier), or may be configured with a computer different from the numerical control apparatus 110 and the driving unit 120.

(Case where there is difference between actual machining unit and simulation unit) (pattern in which contact is detected only by simulation unit)
<2-1>

As shown in FIG. 5B, for example, the numerical control apparatus 110 creates the time-series data Xs(0), Xs(1), . . . , Xs(n) of the machine coordinates Xs(i) of the virtual movable unit 134s or 136s after time Ts(i) seconds from the start time Ts(0), as the operation data for the simulation unit 14 similarly to the above. Further, for example, the numerical control apparatus 110 creates the time-series data Xr(0), Xr(1), . . . , Xr(n) of the machine coordinates Xr(j) of the movable unit 134 or 136 after time Tr(j) seconds from the start time Tr(0), as the operation data for the actual machining unit 12 similarly to the above.

<2-2>

Similarly to the above, the simulation unit 14 performs simulation of machining of the virtual workpiece Ws, and, as shown in FIG. 5B, the numerical control apparatus 110 (the virtual load acquisition unit 18) acquires the contact flag 0/1 (virtual load information) in association with the machine coordinates Xs(i) (comparison position identification data).

<2-3>

Similarly to the above, the driving unit 120 and the actual machining unit 12 machine the workpiece W, and the driving unit 120 (the actual load acquisition unit 16) acquires a contact signal (actual load information) in association with the machine coordinates Xr(j) (comparison position identification data). For example, in FIG. 5B, the tool T and the workpiece W do not come into contact with each other due to damage or incorrect mounting of the tool, and the driving unit 120 (the actual load acquisition unit 16) does not acquire a contact signal and does not output a contact signal to the numerical control apparatus 110.

When contact is detected at a different position after machining has been progressed to some extent, the driving unit 120 (the actual load acquisition unit 16) may output a contact signal (actual load information) and machine coordinates Xr(k) (comparison position identification data) to the numerical control apparatus 110.

<2-4>

Similarly to the above, the numerical control apparatus 110 (the load information determination unit 22) compares the contact signal (actual load information) with the contact flag (virtual load information) based on the machine coordinates Xr(j) and Xs(i) (comparison position identification data) and determines whether or not there is a difference between the pieces of information. For example, in FIG. 5B, though the numerical control apparatus 110 (the load information determination unit 22) does not acquire a contact signal (actual load information) in the actual machining unit 12, the contact flag (virtual load information) 1 exists in the simulation unit 14. Therefore, the numerical control apparatus 110 (the load information determination unit 22) determines that there is a difference between the pieces of information. Or alternatively, since none of the machine coordinates Xr(k) (comparison position identification data) at which the contact signal (actual load information) has been detected in the actual machining unit 12 and the machine coordinates Xs(i−1) and Xs(i) (comparison position identification data) at which the contact flag (virtual load information) changes from 0 to 1 in the simulation unit 14 do not satisfy the following inequality for any of the axes p operating between i−1 and i, the numerical control apparatus 110 (the load information determination unit 22) determines that there is a difference between the actual load information and the virtual load information.

|Xrp(k)−Xsp(i)|≤|Xsp(i)−Xsp(i−1)|

When there is a difference between the actual load information and the virtual load information, the numerical control apparatus 110 (the operation control unit 24) decelerates and stops the machine tool 130. The numerical control apparatus 110 (the operation control unit 24) may immediately stop output of the motor or may perform an emergency stop operation specified in advance. That is, the numerical control apparatus 110 (the operation control unit 24) performs restriction of output for causing the movable unit 134 or 136 to operate, a preset retraction operation of the movable unit 134 or 136, or immediate decelerating and stopping of operation of the movable unit 134 or 136, in the actual machining unit 12.

At this time, an operator of the machine tool can recognize incorrect mounting or damage of the tool T by comparing machine coordinates at which contact (interference) has not been detected in actual machining, corresponding to machine coordinates at which contact (interference) has been detected in machining simulation, and machine coordinates at which contact (interference) has been detected in the actual machining.

(Case where there is difference between actual machining unit and simulation unit) (pattern in which contact is detected only by actual machining unit)
<2-1>

As shown in FIG. 5C, for example, the numerical control apparatus 110 creates the time-series data Xs(0), Xs(1), . . . , Xs(n) of the machine coordinates Xs(i) of the virtual movable unit 134s or 136s after time Ts(i) seconds from the start time Ts(0), as the operation data for the simulation unit 14 similarly to the above. Further, for example, the numerical control apparatus 110 creates the time-series data Xr(0), Xr(1), . . . , Xr(n) of the machine coordinates Xr(j) of the movable unit 134 or 136 after time Tr(j) seconds from the start time Tr(0), as the operation data for the actual machining unit 12 similarly to the above.

<2-2>

Similarly to the above, the simulation unit 14 performs simulation of machining of the virtual workpiece Ws, and, as shown in FIG. 5B, the numerical control apparatus 110 (the virtual load acquisition unit 18) acquires the contact flag 0/1 (virtual load information) in association with the machine coordinates Xs(i) (comparison position identification data). In FIG. 5C, at certain machine coordinates Xs(i) at certain time Ts(i), the virtual tool Ts does not move from the outside to the inside of the virtual workpiece Ws, and the simulation unit 14 sets the contact flag to 0.

When contact is detected at a different position after machining has been progressed to some extent, the numerical control apparatus 110 (the virtual load acquisition unit 18) may acquire the contact flag 1 (virtual load information) in association with machine coordinates Xs(k) (comparison position identification data) at which the contact has been detected.

<2-3>

Similarly to the above, the driving unit 120 and the actual machining unit 12 machine the workpiece W, and the driving unit 120 (the actual load acquisition unit 16) acquires a contact signal (actual load information) in association with the machine coordinates Xr(j) (comparison position identification data).

<2-4>

Similarly to the above, the numerical control apparatus 110 (the load information determination unit 22) compares the contact signal (actual load information) with the contact flag (virtual load information) based on the machine coordinates Xr(j) and Xs(i) (comparison position identification data) and determines whether or not there is a difference between the pieces of information. For example, in FIG. 5C, since the contact flag (virtual load information) is 0 at the machine coordinates Xs(i) (comparison position identification data) in the simulation unit 14, which correspond to the machine coordinates Xr(j) (comparison position identification data) at which the contact signal (actual load information) has been detected in the actual machining unit 12, the numerical control apparatus 110 (the load information determination unit 22) determines that there is a difference between the pieces of information. Or alternatively, since none of the machine coordinates Xr(j) (comparison position identification data) at which the contact signal (actual load information) has been detected in the actual machining unit 12 and the machine coordinates Xs(k−1) and Xs(k) (comparison position identification data) at which the contact flag (virtual load information) changes from 0 to 1 in the simulation unit 14 do not satisfy the following inequality for any of the axes p operating between i−1 and i, the numerical control apparatus 110 (the load information determination unit 22) determines that there is a difference between the actual load information and the virtual load information.

|Xrp(j)−Xsp(k)|≤|Xsp(k)−Xsp(k−1)|

Similarly to the above, when there is a difference between the actual load information and the virtual load information, the numerical control apparatus 110 (the operation control unit 24) decelerates and stops the machine tool 130.

### Example 3

In the example 3, the operation data is used as the pieces of comparison position identification data. By writing machine coordinates in the operation data, it becomes easy to identify a position of a problem in machining data. FIG. 6A is a diagram showing a case where there is no difference between the actual load information about the movable unit of the actual machining unit and the virtual load information about the virtual movable unit of the simulation unit; and FIG. 6B is a diagram showing a case where there is a difference between the actual load information about the movable unit of the actual machining unit and the virtual load information about the virtual movable unit of the simulation unit (a pattern in which contact is detected only by the simulation unit). FIG. 6C is a diagram showing a case where there is a difference between the actual load information about the movable unit of the actual machining unit and the virtual load information about the virtual movable unit of the simulation unit (a pattern in which contact is detected only by the actual machining unit).

(Case where there is no difference between actual machining unit and simulation unit)
<3-1>

As shown in FIG. 6A, for example, the simulation unit 14 analyzes the machining program, creates the time-series data Xs(0), Xs(1), . . . , Xs(n) of the machine coordinates Xs(i) of the virtual movable unit 134s or 136s after time Ts(i) seconds from the start time Ts(0), as the operation data for the simulation unit 14. Meanwhile, for example, the numerical control apparatus 110 analyzes the machining program, creates time-series data Xr(0), Xr(1), . . . , Xr(n) of the machine coordinates Xr(j) of the movable unit 134 or 136 after time Tr(j) seconds from the start time Tr(0), as the operation data for the actual machining unit 12, and outputs the time-series data Xr(0), Xr(1), . . . , Xr(n) to the driving unit 120. Here, i and j are arbitrary integers between 1 and n. n is an integer equal to or larger than 1.

<3-2>

The simulation unit 14 performs simulation of machining of the virtual workpiece Ws by relatively moving the virtual tool Ts and the virtual workpiece Ws based on the machine coordinates Xs(0), . . . , Xs(n) (operation data).

The simulation unit 14 calculates contact information indicating whether or not the virtual tool Ts and the virtual workpiece Ws are in contact with each other, as information about a virtual load that occurs on the virtual movable unit 134s or 136s, at certain machine coordinates Xs(i) at certain time Ts(i). Further, the simulation unit 14 calculates the certain machine coordinates Xs(i) at the certain time Ts(i) as comparison position identification data that identifies a position of comparison between the virtual load information and the actual load information. For example, when the virtual tool Ts comes into the inside from the outside of the virtual workpiece Ws, between the machine coordinates Xs(j−1) and Xs(j), the simulation unit 14 adds the coordinates of the machine coordinates Xs(j) in the format of “,Ln X_Y_Z_” in association with a command block in the operation data (virtual load information and comparison position identification data). Here, n is an integer equal to or larger than 1, and n is incremented and written multiple times when contact occurs multiple times during one block.

When the operation data is micro line segments, the coordinates of the machine coordinates Xs(j) may be added not for each command block but for each block (virtual load information and comparison position identification data). Further, though the case where there are three feed axes has been exemplified, the present embodiment is also applicable to a case where there are four or more feed axes.

The pieces of comparison position identification data are data that associate time-series or machining positions between the virtual load information and the actual load information. More specifically, the pieces of comparison position identification data are data that cause the machine coordinates Xs(i) at which the virtual tool Ts and the virtual workpiece Ws come into contact with each other in the simulation unit 14 and the machine coordinates Xr(j) at which the tool T and the workpiece W come into contact with each other in the actual machining unit 12 to correspond to each other one-to-one. That is, the pieces of comparison position identification data are data that identify the machine coordinates Xs(i) and the machine coordinates Xr(j) as the comparison positions of the virtual load information and the actual load information. Thereby, the load information determination unit 22 can appropriately compare the virtual load information at the machine coordinates Xs(i) with the actual load information at the machine coordinates Xr(j) based on the pieces of comparison position identification data.

As shown in FIG. 6A, the numerical control apparatus 110 (the virtual load acquisition unit 18) acquires “,Ln X_Y_Z_” (virtual load information and comparison position identification data) added to the operation data.

The simulation unit 14 performs the machining simulation described above before the actual machining unit 12 operates based on the operation data, and calculates the virtual load information and the comparison position data in advance. Further, the virtual load acquisition unit 18 may acquire the virtual load information in association with the comparison position identification data in advance before the actual machining unit 12 operates based on the operation data and temporarily store the virtual load information and the comparison position identification data in the storage unit 20.

<3-3>

The driving unit 120 drives the motor 132 and the movable unit 134 or 136 of the actual machining unit 12 based on the machine coordinates Xr(0), . . . , Xr(n) (operation data) output from the numerical control apparatus 110. Thereby, the actual machining unit 12 machines the workpiece W by relatively moving the tool T and the workpiece W.

The driving unit 120 (the actual load acquisition unit 16) acquires contact information indicating whether or not the tool T and the workpiece W are in contact with each other, as information about a load that occurs on the movable unit 134 or 136, at certain machine coordinates Xr(j) at certain time Tr(j). For example, the driving unit 120 (the actual load acquisition unit 16) monitors output of the motor 132 (commands or feedback information), determines that the tool T and the workpiece W have come into contact with each other when the output of the motor 132 exceeds a certain threshold, and outputs a contact signal to the numerical control apparatus 110.

The driving unit 120 (the actual load acquisition unit 16) acquires the contact signal (actual load information) in association with the machine coordinates Xr(j) (comparison position identification data).

<3-4>

The numerical control apparatus 110 (the load information determination unit 22) compares the contact signal (actual load information) with whether contact has been made or not (virtual load information) based on the machine coordinates Xr(j) and Xs(i) (comparison position identification data), and determines whether or not there is a difference between the pieces of information. For example, in FIG. 6A, since the machine coordinates Xr(j) (comparison position identification data) at which the contact signal (actual load information) has been detected in the actual machining unit 12, and the machine coordinates Xs(i) indicated by “,Ln X_Y_Z_” added to the operation data in the simulation unit 14 (comparison position identification data) satisfy the following inequality for all the axes p operating between i−1 to i, the numerical control apparatus 110 (the load information determination unit 22) determines that there is no difference between the actual load information and the virtual load information.

|Xrp(j)−Xsp(i)|≤|Xsp(i)−Xsp(i−1)|

When “,Ln X_Y_Z_” (virtual load information and comparison position identification data) is written at a plurality positions in the operation data, the above determination can be performed in ascending order of the values of n.

The load information determination unit 22 performs the determination described above in real time while the actual machining unit 12 is operating, based on the virtual load information obtained by the simulation unit 14 in advance and the actual load information obtained by the actual machining unit 12 in real time. The load information determination unit 22 may extract only virtual load information and actual load information in a certain particular section in the pieces of comparison position identification data and compare the virtual load information with the actual load information.

When there is no difference between the actual load information and the virtual load information, the numerical control apparatus 110 (the operation control unit 24) does not restrict operation.

Since the cycle of acquiring the position of the movable unit in the actual machining unit is generally shorter than a simulation cycle, an error of the machine coordinates Xr(j) at which the contact signal has been detected in the actual machining unit 12 can be ignored. When the error of the simulation unit 14 is smaller than an error of the actual machining unit, however, the load information determination unit 22 may determine that there is no difference between the actual load information and the virtual load information if such machine coordinates Xs(i) that come into contact in the simulation unit 14 exist between machine coordinates Xr(j−1) and Xr(j) in the actual machining unit 12. That is, it may be confirmed that the following equality holds for all the axes p operating between i−1 and i.

|Xrp(j)−Xsp(i)|≤|Xrp(j)−Xrp(j−1)|

(Case where there is difference between actual machining unit and simulation unit) (pattern in which contact is detected only by simulation unit)
<3-1>

As shown in FIG. 6B, for example, the simulation unit 14 creates the time-series data Xs(0), Xs(1), . . . , Xs(n) of the machine coordinates Xs(i) of the virtual movable unit 134s or 136s after time Ts(i) seconds from the start time Ts(0), as the operation data for the simulation unit 14 similarly to the above. Meanwhile, for example, the numerical control apparatus 110 creates the time-series data Xr(0), Xr(1), . . . , Xr(n) of the machine coordinates Xr(j) of the movable unit 134 or 136 after time Tr(j) seconds from the start time Tr(0), as the operation data for the actual machining unit 12 similarly to the above.

<3-2>

Similarly to the above, the simulation unit 14 performs simulation of machining of the virtual workpiece Ws, and the numerical control apparatus 110 (the virtual load acquisition unit 18) acquires “,Ln X_Y_Z_” (virtual load information and comparison position identification data) added to the operation data as shown in FIG. 6B.

<3-3>

Similarly to the above, the driving unit 120 and the actual machining unit 12 machine the workpiece W, and the driving unit 120 (the actual load acquisition unit 16) acquires a contact signal (actual load information) in association with the machine coordinates Xr(j) (comparison position identification data). For example, in FIG. 6B, the tool T and the workpiece W do not come into contact with each other due to damage or incorrect mounting of the tool, and the driving unit 120 (the actual load acquisition unit 16) does not acquire a contact signal and does not output a contact signal to the numerical control apparatus 110.

<3-4>

Similarly to the above, the numerical control apparatus 110 (the load information determination unit 22) compares the contact signal (actual load information) with whether contact has been made or not (virtual load information) based on the machine coordinates Xr(j) and Xs(i) (comparison position identification data), and determines whether or not there is a difference between the pieces of information. For example, in FIG. 6B, since the driving unit 120 (the actual load acquisition unit 16) does not acquire a contact signal even though a block (comparison position identification data) corresponding to a block in which “,Ln X_Y_Z_” (virtual load information and comparison position identification data) in the operation data of the simulation unit 14 is written has passed, the numerical control apparatus 110 (the load information determination unit 22) determines that there is a difference between the pieces of information.

When there is a difference between the actual load information and the virtual load information, the numerical control apparatus 110 (the operation control unit 24) decelerates and stops the machine tool 130. The numerical control apparatus 110 (the operation control unit 24) may immediately stop output of the motor or may perform an emergency stop operation specified in advance. That is, the numerical control apparatus 110 (the operation control unit 24) performs restriction of output for causing the movable unit 134 or 136 to operate, a preset retraction operation of the movable unit 134 or 136, or immediate decelerating and stopping of operation of the movable unit 134 or 136, in the actual machining unit 12.

Further, the display unit 28 may display the machine coordinates Xs(i) of the operation data at which contact (interference) between the virtual tool Ts and the virtual workpiece Ws has been detected in the simulation unit 14, in a color different from that of other operation data or may blinkingly display the machine coordinates Xs(i). Thereby, the operator of the machine tool can easily recognize the machine coordinates Xs(i) of the operation data at which contact (interference) between the virtual tool Ts and the virtual workpiece Ws has been detected in the simulation unit 14.

(Case where there is difference between actual machining unit and simulation unit) (pattern in which contact is detected only by actual machining unit)
<3-1>

As shown in FIG. 6C, for example, the simulation unit 14 creates the time-series data Xs(0), Xs(1), . . . , Xs(n) of the machine coordinates Xs(i) of the virtual movable unit 134s or 136s after time Ts(i) seconds from the start time Ts(0), as the operation data for the simulation unit 14 similarly to the above. Meanwhile, for example, the numerical control apparatus 110 creates the time-series data Xr(0), Xr(1), . . . , Xr(n) of the machine coordinates Xr(j) of the movable unit 134 or 136 after time Tr(j) seconds from the start time Tr(0), as the operation data for the actual machining unit 12 similarly to the above.

<3-2>

Similarly to the above, the simulation unit 14 performs simulation of machining of the virtual workpiece Ws, and the numerical control apparatus 110 (the virtual load acquisition unit 18) acquires “,Ln X_Y_Z_” (virtual load information and comparison position identification data) added to the operation data as shown in FIG. 6C. For example, in FIG. 6C, since the virtual tool Ts does not come into the inside from the outside of the virtual workpiece Ws, and “,Ln X_Y_Z_” (virtual load information and comparison position identification data) is not written in the operation data, the numerical control apparatus 110 (the virtual load acquisition unit 18) does not acquire “,Ln X_Y_Z_” (virtual load information and comparison position identification data) added to the operation data.

<3-3>

Similarly to the above, the driving unit 120 and the actual machining unit 12 machine the workpiece W, and the driving unit 120 (the actual load acquisition unit 16) acquires a contact signal (actual load information) in association with the machine coordinates Xr(j) (comparison position identification data).

<3-4>

Similarly to the above, the numerical control apparatus 110 (the load information determination unit 22) compares the contact signal (actual load information) with whether contact has been made or not (virtual load information) based on the machine coordinates Xr(j) and Xs(i) (comparison position identification data), and determines whether or not there is a difference between the pieces of information. For example, in FIG. 6C, since “,Ln X_Y_Z_” (virtual load information and comparison position identification data) is not written in a block of the operation data of the simulation unit 14, which corresponds to the machine coordinates Xr(j) (comparison position identification data) at which the contact signal (actual load information) has been detected in the actual machining unit 12, the numerical control apparatus 110 (the load information determination unit 22) determines that there is a difference between the pieces of information.

Similarly to the above, when there is a difference between the actual load information and the virtual load information, the numerical control apparatus 110 (the operation control unit 24) decelerates and stops the machine tool 130.

Further, similarly to the above, the display unit 28 may display the machine coordinates Xr(j) at which contact (interference) between the tool T and the workpiece W has been detected in the actual machining unit 12, in a color different from that of other operation data or may blinkingly display the machine coordinates Xr(j). Thereby, the operator of the machine tool can easily recognize the machine coordinates Xr(j) at which contact (interference) between the tool T and the workpiece W has been detected in the actual machining unit 12.

### Example 4

In the example 4, the magnitude of a load (energy) that occurs on the movable unit at the time of machining the workpiece is used as the actual load information, and the magnitude of a load (energy) that occurs on the virtual movable unit at the time of machining the virtual workpiece is used as the virtual load information. By acquiring the magnitude of the load (energy) instead of whether contact has been made or not, it becomes possible to more accurately determine contact between the tool and the workpiece, for example, at the time of performing gradual cutting.

<4-1>

As shown in FIG. 7, for example, the numerical control apparatus 110 analyzes the machining program, creates the time-series data Xs(0), Xs(1), . . . , Xs(n) of the machine coordinates Xs(i) of the virtual movable unit 134s or 136s after time Ts(i) seconds from the start time Ts(0), as the operation data for the simulation unit 14, and outputs the time-series data Xs(0), Xs(1), . . . , Xs(n) to the simulation unit 14. Further, for example, the numerical control apparatus 110 analyzes the machining program, creates time-series data Xr(0), Xr(1), . . . , Xr(n) of the machine coordinates Xr(j) of the movable unit 134 or 136 after time Tr (j) seconds from the start time Tr(0), as the operation data for the actual machining unit 12, and outputs the time-series data Xr(0), Xr(1), . . . , Xr(n) to the driving unit 120. Here, i and j are arbitrary integers between 1 and n. n is an integer equal to or larger than 1.

In the present embodiment, the form of the numerical control apparatus 110 analyzing the machining program and creating the time-series data of machine coordinates (operation data) is exemplified. The present embodiment, however, is not limited thereto, and the computer constituting the simulation unit 14 or another computer may analyze the machining program and create the time-series data of machine coordinates (operation data).

<4-2>

The simulation unit 14 performs simulation of machining of the virtual workpiece Ws by relatively moving the virtual tool Ts and the virtual workpiece Ws based on the machine coordinates Xs(0), . . . , Xs(n) (operation data) output from the numerical control apparatus 110.

The simulation unit 14 calculates a total amount of virtual load Ws(i) [J/s](energy Ws×t) as information about a virtual load that occurs on the virtual movable unit 134s or 136s, at certain machine coordinates Xs(i) at certain time Ts(i).

An example of calculation of the total amount of virtual load Ws(i) [J/s](energy Ws×t) will be shown below. Consideration will be made on a case where the virtual movable unit 134s or 136s moves from the machine coordinates Xs(i−1) at the time Ts(i−1) to the machine coordinates Xs(i) at the time Ts(i). When it is assumed that energy for performing removal machining of the virtual workpiece Ws is proportional to volume to be removed (a proportionality constant k), and a total amount of friction coefficients in the case of causing the movable unit with a mass of m to operate remains constant (n), a total amount of virtual load Ws(i) per hour from time T(i−1) to T(i) can be expressed by the following formula:

$$Ws ( i ) = \frac{Es ( i )}{Δ Ts} \qquad [ Formula 1 ]$$

$$\begin{matrix}Es ( i ) = kVs ( i ) \\ + ( \frac{1}{2} {{mv}_{s} ( i )}^{2} - \frac{1}{2} {{mv}_{s} ( i - 1 )}^{2} ) \\ + φ ( Xs ( i ) ) - φ ( Xs ( i - 1 ) ) \\ + nmg \vert Xs ( i ) - Xs ( i - 1 ) \vert\end{matrix}$$

As for the numerator of the right side of the above formula, the first term represents energy for performing removal machining of the virtual workpiece Ws; the second term represents an amount of change in motive energy; the third term represents an amount of change in potential energy; and the fourth term represents energy consumed by motion of the virtual movable unit.

Here, Vs(i) represents the volume of an area to be removed and represents an area where an area through which the virtual tool Ts has passed and the area of the virtual workpiece Ws overlapped between Ts(i−1) to Ts(i). Further, Vs(i) represents the speed of i and can be expressed by the following formula:

$${v}_{s} ( i ) = \frac{\vert Xs ( i ) - Xs ( i - 1 ) \vert}{Δ Ts} \qquad [ Formula 2 ]$$

Further, the simulation unit 14 calculates the certain machine coordinates Xs(i) at the certain time Ts(i) as comparison position identification data that identifies a position of comparison between the virtual load information and the actual load information. Specifically, the pieces of comparison position identification data are data that associate time-series or machining positions between the virtual load information and the actual load information. More specifically, the pieces of comparison position identification data are data that cause time Ts(i) when the virtual tool Ts and the virtual workpiece Ws come into contact with each other in the simulation unit 14 and time Tr(j) when the tool T and the workpiece W come into contact with each other in the actual machining unit 12 to correspond to each other one-to-one. That is, the pieces of comparison position identification data are data that identify the time Ts(i) and the time Tr(j) as the comparison positions of the virtual load information and the actual load information. Thereby, the load information determination unit 22 can appropriately compare the virtual load information at the time Ts(i) with the actual load information at the time Tr(j) based on the pieces of comparison position identification data. As described above, the simulation unit 14 may be provided in the numerical control apparatus 110 or may be configured with a computer different from the numerical control apparatus 110.

As shown in FIG. 7, the numerical control apparatus 110 (the virtual load acquisition unit 18) acquires the load Ws(i) [J/s](energy Ws×t) (virtual load information) in association with the time Ts(i) (comparison position identification data).

The simulation unit 14 performs the machining simulation described above before the actual machining unit 12 operates based on the operation data, and calculates the virtual load information and the comparison position data in advance.

Further, the virtual load acquisition unit 18 may acquire the virtual load information in association with the piece of comparison position identification data in advance before the actual machining unit 12 operates based on the operation data and temporarily store the virtual load information and the comparison position identification data in the storage unit 20.

<4-3>

The driving unit 120 drives the motor 132 and the movable unit 134 or 136 of the actual machining unit 12 based on the machine coordinates Xr(0), . . . , Xr(n) (operation data) output from the numerical control apparatus 110. Thereby, the actual machining unit 12 machines the workpiece W by relatively moving the tool T and the workpiece W.

The driving unit 120 (the actual load acquisition unit 16) calculates a total amount of motor load Wr(j) [J/s](energy Wr×t), as information about an actual load that occurs on the movable unit 134 or 136, at certain machine coordinates Xr(j) at certain time Tr(j). The calculation of the load Wr(j) [J/s](energy Wr×t) can be similar to the example of calculation of the load Ws(i) [J/s] (energy Ws×t) described above.

When the machine tool is an electric spark machine, power that flows through the tool can be added to the total amount of motor load.

As shown in FIG. 7, the driving unit 120 (the actual load acquisition unit 16) acquires the load Wr(j) [J/s] (energy Wr×t) (actual load information) in association with the time Tr(j) (comparison position identification data).

<4-4>

The numerical control apparatus 110 (the load information determination unit 22) compares the load Wr(j) [J/s](energy Wr×t) (actual load information) with the load Ws(i) [J/s](energy Ws×t) (virtual load information) based on the time Tr(j) and Ts(i) (comparison position identification data) and determines whether or not there is a difference between the pieces of information. For example, in FIG. 7, the numerical control apparatus 110 (the load information determination unit 22) determines the minimum j (jmin) and the maximum j (jmax) that satisfy the following formula at the time of Ts(i):

Ts(i−1)≤Tr(j)<Ts(i)

The numerical control apparatus 110 (the load information determination unit 22) determines whether or not the following formula is satisfied in the case of i. If the following formula is satisfied, the numerical control apparatus 110 (the load information determination unit 22) determines that there is no difference between the actual load information and the virtual load information.

$$\vert \begin{matrix} & \\ Ws ( i ) Δ Ts & - {\sum }_{k = {j}_{min}}^{{j}_{max} - {j}_{min} + 1} \\ & \end{matrix} ( Wr ( k ) Δ Tr ) \vert \leq Δ W \qquad [ Formula 3 ]$$

Here, jmin and jmax represent the minimum and maximum j satisfying Ts(i−1)≤Tr(j)<Ts(i); ΔTs represents a simulation cycle; ΔTr represents a cycle of acquiring motor output in the actual machining unit; and ΔW[J] represents a certain threshold indicating a motor load. The above formula assumes ΔTs>ΔTr.

When the motor output is smaller than the threshold, the comparison may not be performed on the assumption that the workpiece and the tool are not in contact with each other in the actual machining unit.

The load information determination unit 22 performs the determination described above in real time while the actual machining unit 12 is operating, based on the virtual load information obtained by the simulation unit 14 in advance and the actual load information obtained by the actual machining unit 12 in real time. The load information determination unit 22 may extract only virtual load information and actual load information in a certain particular section in the pieces of comparison position identification data and compare the virtual load information with the actual load information.

When there is no difference between the actual load information and the virtual load information, the numerical control apparatus 110 (the operation control unit 24) does not restrict operation.

As described above, the load information determination unit 22 may be provided in the numerical control apparatus 110, may be provided in the driving unit 120 (a servo control unit or an amplifier), or may be configured with a computer different from the numerical control apparatus 110 and the driving unit 120.

### Example 5

In the examples 1 to 4 described above, the form of restricting operation of actual machining on the assumption that there is something wrong in the actual machining has been exemplified. In the example, 5, when there is something wrong in settings for machining simulation, the settings for machining simulation are changed (corrected). Thus, by reflecting a difference between the actual load information and the virtual load information on machining simulation, it is possible to improve simulation accuracy.

<5-1>

As shown in FIG. 8, for example, the numerical control apparatus 110 analyzes the machining program, creates the time-series data Xs(0), Xs(1), . . . , Xs(n) of the machine coordinates Xs(i) of the virtual movable unit 134s or 136s after time Ts(i) seconds from the start time Ts(0), as the operation data for the simulation unit 14, and outputs the time-series data Xs(0), Xs(1), . . . , Xs(n) to the simulation unit 14. Further, for example, the numerical control apparatus 110 analyzes the machining program, creates time-series data Xr(0), Xr(1), . . . , Xr(n) of the machine coordinates Xr(j) of the movable unit 134 or 136 after time Tr(j) seconds from the start time Tr(0), as the operation data for the actual machining unit 12, and outputs the time-series data Xr(0), Xr(1), . . . , Xr(n) to the driving unit 120. Here, i and j are arbitrary integers between 1 and n. n is an integer equal to or larger than 1.

In the present embodiment, the form of the numerical control apparatus 110 analyzing the machining program and creating the time-series data of machine coordinates (operation data) is exemplified. The present embodiment, however, is not limited thereto, and the computer constituting the simulation unit 14 or another computer may analyze the machining program and create the time-series data of machine coordinates (operation data).

<5-2>

The driving unit 120 drives the motor 132 and the movable unit 134 or 136 of the actual machining unit 12 based on the machine coordinates Xr(0), . . . , Xr(n) (operation data) output from the numerical control apparatus 110. Thereby, the actual machining unit 12 machines the workpiece W by relatively moving the tool T and the workpiece W.

The driving unit 120 (the actual load acquisition unit 16) acquires contact information indicating whether or not the tool T and the workpiece W are in contact with each other, as information about a load that occurs on the movable unit 134 or 136, at certain machine coordinates Xr(j) at certain time Tr(j). For example, the driving unit 120 (the actual load acquisition unit 16) monitors output of the motor 132 (commands or feedback information), sets the contact signal to 0 when the output of the motor 132 does not exceed a certain threshold, and sets the contact signal to 1 when the output of the motor 132 exceeds the certain threshold, determining that the tool T and the workpiece W have come into contact with each other.

The driving unit 120 (the actual load acquisition unit 16) acquires the contact signal (actual load information) in association with the machine coordinates Xr(j) (comparison position identification data).

The pieces of comparison position identification data are data that associate time-series or machining positions between the virtual load information and the actual load information. More specifically, the pieces of comparison position identification data are data that cause the machine coordinates Xs(i) at which the virtual tool Ts and the virtual workpiece Ws come into contact with each other in the simulation unit 14 and the machine coordinates Xr(j) at which the tool T and the workpiece W come into contact with each other in the actual machining unit 12 to correspond to each other one-to-one. That is, the pieces of comparison position identification data are data that identify the machine coordinates Xs(i) and the machine coordinates Xr(j) as the comparison positions of the virtual load information and the actual load information. Thereby, the load information determination unit 22 can appropriately compare the virtual load information at the machine coordinates Xs(i) with the actual load information at the machine coordinates Xr(j) based on the pieces of comparison position identification data.

<5-3>

The simulation unit 14 performs simulation of machining of the virtual workpiece Ws by relatively moving the virtual tool Ts and the virtual workpiece Ws based on the machine coordinates Xs(0), . . . , Xs(n) (operation data) output from the numerical control apparatus 110.

The simulation unit 14 calculates contact information indicating whether or not the virtual tool Ts and the virtual workpiece Ws are in contact with each other, as information about a virtual load that occurs on the virtual movable unit 134s or 136s, at certain machine coordinates Xs(i) at certain time Ts(i). For example, the simulation unit 14 sets the contact flag to 0 when the virtual tool Ts is outside the virtual workpiece Ws, and sets the contact flag to 1 when the virtual tool Ts moves from the outside to the inside of the virtual workpiece Ws.

Further, the simulation unit 14 calculates the certain machine coordinates Xs(i) at the certain time Ts(i) as comparison position identification data that identifies a position of comparison between the virtual load information and the actual load information. As described above, the simulation unit 14 may be provided in the numerical control apparatus 110 or may be configured with a computer different from the numerical control apparatus 110.

The numerical control apparatus 110 (the virtual load acquisition unit 18) acquires the contact flag 0/1 (virtual load information) in association with the machine coordinates Xs(i) (comparison position identification data).

<5-4>

The simulation unit 14 (the load information determination unit 22) compares the contact signal (actual load information) with the contact flag (virtual load information) based on the machine coordinates Xr(j) and Xs(i) (comparison position identification data) and determines whether or not there is a difference between the pieces of information. For example, in FIG. 8, when the machine coordinates Xr(j) (comparison position identification data) at which the contact signal (actual load information) has been detected in the actual machining unit 12 and the machine coordinates Xs(i) (comparison position identification data) at which the contact flag (virtual load information) changes from 0 to 1 in the simulation unit 14 are different, based on the machine coordinates Xr(j) and Xs(i) (comparison position identification data), the numerical control apparatus 110 (the load information determination unit 22) determines that there is a difference between the actual load information and the virtual load information.

The load information determination unit 22 may extract only virtual load information and actual load information in a certain particular section in the pieces of comparison position identification data and compare the virtual load information with the actual load information.

When there is a difference between the actual load information and the virtual load information, the simulation unit 14 (the correction unit 26) changes (corrects) the prerequisites for the simulation unit 14. As the prerequisites for the simulation unit 14, for example, items written in the operation data, which are prerequisites about a virtual tool, a virtual workpiece, and a virtual movable unit, are included.

For example, in FIG. 8, the simulation unit 14 (the correction unit 26) calculates a difference between machine coordinates in the simulation unit 14, which correspond to the machine coordinates Xr(j) at which the contact signal (actual load information) has been detected in the actual machining unit 12 and machine coordinates of a boundary of the virtual workpiece Ws, and reflects the difference on the prerequisites for the simulation unit so as to make a change, with the difference as a set value of a radius R of the virtual tool Ts.

Or alternatively, the simulation unit 14 (the correction unit 26) may calculate a difference between the machine coordinates Xr(j) at which the contact signal (actual load information) has been detected in the actual machining unit 12 and the machine coordinates Xs(i) at which the contact flag (virtual load information) has been detected in the simulation unit 14, set the difference as a correction amount of the virtual tool Ts, and reflect the difference on the prerequisites for the simulation unit to change (correct) the set value for the virtual tool Ts by the correction amount.

Or alternatively, the simulation unit 14 (the correction unit 26) may identify, based on the machine coordinates Xr(j) (comparison position identification data) at which the contact signal (actual load information) has been detected in the actual machining unit 12 and the machine coordinates Xs(i) (comparison position identification data) at which the contact flag (virtual load information) changes from 0 to 1 in the simulation unit 14, such a process that there is a difference between the pieces of information in the operation data, and change (correct) the prerequisites for machining simulation.

As described above, according to the machining load determination system 10 of the present embodiment, virtual load information about machining simulation is acquired in association with comparison position identification data, and actual load information about actual machining is acquired in association with comparison position identification data, and, therefore, it is possible to appropriately compare the pieces of load information based on the pieces of comparison position identification data, without performing the machining simulation for the actual machining in real time. Therefore, it is possible to perform machining simulation in advance before actual machining; it is not necessary to shorten processing time of the machining simulation according to operation time of the actual machining; and the accuracy of the machining simulation is not limited. That is, the accuracy of the machining simulation can be enhanced. Therefore, it is possible to enhance the accuracy of detection of a difference between the machining simulation and the actual machining and correctly detect such malfunctions that it has conventionally not been possible to prevent.

Here, in the technique disclosed in Patent Document 1, it is necessary to, in the case of repeating the same operation with the same operation data, continue the same simulation all the time, and resources therefore are required. With regard to this point, it is not necessary, in the present embodiment, to perform machining simulation each time actual machining is performed, and resources can be reduced in comparison with the technique disclosed in Patent Document 1.

The present disclosure has been described in detail, but the present disclosure is not limited to the individual embodiments described above. For the above embodiments, various additions, replacements, changes, partial deletions, and the like are possible within a range not departing from the spirit of the present disclosure or within a range not departing from the spirit of the present disclosure derived from the content written in CLAIMS and equivalents to the content. Further, the above embodiments can be implemented in combination. For example, in the embodiments described above, order of operations and order of processes are shown as examples, and the present disclosure is not limited thereto. The same goes for the cases where numerical values or formulas are used in the description of the embodiments described above.

As for the above embodiments and modifications, the following additional remarks are further disclosed.

### (Additional Remark 1)

A machining load determination system (10) includes:
an actual machining unit (12) that includes a movable unit (134 or 136) provided with a tool (T) or a machining target object (W) and machines the machining target object (W) by relatively moving the tool (T) and the machining target object (W) based on operation data;
a simulation unit (14) that performs, in a virtual space (VS) including a virtual tool (Ts), a virtual machining target object (Ws), and a virtual movable unit (134s or 136s) corresponding to the tool (T), the machining target object (W), and the movable unit (134 or 136), respectively, machining simulation of machining the virtual machining target object (Ws) by relatively moving the virtual tool (Ts) and the virtual machining target object (Ws) based on the operation data;
a virtual load acquisition unit (18) that acquires virtual load information about a virtual load that occurs on the virtual movable unit (134s or 136s), the virtual load information having been obtained by way of the machining simulation by the simulation unit (14);
an actual load acquisition unit (16) that acquires actual load information about an actual load that occurs on the movable unit (134 or 136), the actual load information having been obtained by way of the machining by the actual machining unit (12); and
a load information determination unit (22) that makes determination as to whether or not there is a difference between the virtual load information and the actual load information by comparing the virtual load information with the actual load information.

The simulation unit (14) calculates the virtual load information, and comparison position identification data identifying a position of comparison between the virtual load information and the actual load information,
the virtual load acquisition unit (18) acquires the virtual load information in association with the comparison position identification data,
the actual load acquisition unit (16) acquires the actual load information in association with the comparison position identification data, and
the load information determination unit (22) compares the virtual load information with the actual load information based on the comparison position identification data.

### (Additional Remark 2)

In the machining load determination system (10),
the comparison position identification data for the actual load information includes at least any of position information about the movable unit (134 or 136) or time information; and
the comparison position identification data for the virtual load information includes at least any of position information about the virtual movable unit (134s or 136s), time information, or the operation data.

### (Additional Remark 3)

In the machining load determination system (10),
the actual load information includes energy that occurs in the movable unit (134 or 136) at a time of machining the machining target object (W), and
the virtual load information includes energy that occurs in the virtual movable unit (134s or 136s) at a time of machining the virtual machining target object (Ws).

### (Additional Remark 4)

In the machining load determination system (10),
the actual load information is contact information indicating whether or not the tool (T) and the machining target object (W) are in contact with each other, and
the virtual load information is contact information indicating whether or not the virtual tool (Ts) and the virtual machining target object (Ws) are in contact with each other.

### (Additional Remark 5)

In the machining load determination system (10),
the load information determination unit (22) makes the determination in real time while the actual machining unit (12) is operating.

### (Additional Remark 6)

In the machining load determination system (10),
in a case where the load information determination unit (22) determines that there is a difference between the virtual load information and the actual load information, the actual machining unit (12) performs at least any of restriction of output for causing the movable unit (134 or 136) to operate, a preset retraction operation of the movable unit (134 or 136), or immediate decelerating and stopping of operation of the movable unit (134 or 136).

### (Additional Remark 7)

In the machining load determination system (10),
the simulation unit (14) performs the machining simulation based on the operation data, the operation data including prerequisites about the virtual tool (Ts), the virtual machining target object (Ws), and the virtual movable unit (134s or 136s), and
in a case where the load information determination unit (22) determines that there is a difference between the virtual load information and the actual load information, the simulation unit (14) identifies, in the operation data, a process where the difference between the virtual load information and the actual load information exists based on the comparison position identification data, and changes the prerequisites for the machining simulation.

### (Additional Remark 8)

In the machining load determination system (10),
the actual load information is contact information indicating whether or not the tool (T) and the machining target object (W) are in contact with each other,
the virtual load information is contact information indicating whether or not the virtual tool (Ts) and the virtual machining target object (Ws) are in contact with each other,
the comparison position identification data for the actual load information includes position information about the movable unit (134 or 136),
the comparison position identification data for the virtual load information includes position information about the virtual movable unit (134s or 136s),
the simulation unit (14) performs the machining simulation based on the operation data that includes prerequisites about the virtual tool (Ts), the virtual machining target object (Ws), and the virtual movable unit (134s or 136s), and
in a case where the load information determination unit (22) determines that there is a difference between the virtual load information and the actual load information, the simulation unit (14) calculates a difference between machine coordinates at which the tool (t) and the machining target object (W) in the actual machining unit (12) have come into contact with each other and machine coordinates at which the virtual tool (Ts) and the virtual machining target object (Ws) in the simulation unit (14) have come into contact with each other, and
the simulation unit (14) changes the prerequisites for the virtual tool (Ts), with the difference as a correction amount for the virtual tool (Ts).

### (Additional Remark 9)

In the machining load determination system (10),
the simulation unit (14) performs the machining simulation before the actual machining unit (12) performs operation based on the operation data, and calculates the comparison position data and the virtual load information.

### (Additional Remark 10)

In the machining load determination system (10),
the virtual load acquisition unit (18) writes at least any of the comparison position identification data or the virtual load information in the operation data.

### (Additional Remark 11)

The machining load determination system (10) includes
a display unit (28) that displays comparison position identification data for which the load information determination unit (22) has determined that there is a difference between the virtual load information and the actual load information, in a display manner varying according to the difference.

### (Additional Remark 12)

In the machining load determination system (10),
the load information determination unit (22) extracts and compares only a part of the virtual load information with only a part of the actual load information corresponding to a certain particular section in the comparison position identification data.

### EXPLANATION OF REFERENCE NUMERALS

10 machining load determination system
12 actual machining unit
14 simulation unit
16 actual load acquisition unit
18 virtual load acquisition unit
20 storage unit
22 load information determination unit
24 operation control unit
26 correction unit
28 display unit
100 industrial machine system
110 numerical control apparatus
120 driving unit
130 machine tool (industrial machine)
83
132 motor
134 mounting unit (movable unit)
134s virtual mounting unit (virtual movable unit)
136 table (movable unit)
136s virtual table (virtual movable unit)
T tool
Ts virtual tool
VS virtual space
W workpiece (machining target object)
Ws virtual workpiece (virtual machining target object)

1. A machining load determination system comprising:
an actual machining unit that comprises a movable unit provided with a tool or a machining target object and machines the machining target object by relatively moving the tool and the machining target object based on operation data;
a simulation unit that performs, in a virtual space including a virtual tool, a virtual machining target object, and a virtual movable unit corresponding to the tool, the machining target object, and the movable unit, respectively, machining simulation of machining the virtual machining target object by relatively moving the virtual tool and the virtual machining target object based on the operation data;
a virtual load acquisition unit that acquires virtual load information about a virtual load that occurs on the virtual movable unit, the virtual load information having been obtained by way of the machining simulation by the simulation unit;
an actual load acquisition unit that acquires actual load information about an actual load that occurs on the movable unit, the actual load information having been obtained by way of the machining by the actual machining unit; and
a load information determination unit that makes determination as to whether or not there is a difference between the virtual load information and the actual load information by comparing the virtual load information with the actual load information, wherein
the simulation unit calculates the virtual load information, and comparison position identification data identifying a position of comparison between the virtual load information and the actual load information,
the virtual load acquisition unit acquires the virtual load information in association with the comparison position identification data,
the actual load acquisition unit acquires the actual load information in association with the comparison position identification data, and
the load information determination unit compares the virtual load information with the actual load information based on the comparison position identification data.

2. The machining load determination system according to claim 1, wherein
the comparison position identification data for the actual load information includes at least any of position information about the movable unit or time information, and
the comparison position identification data for the virtual load information includes at least any of position information about the virtual movable unit, time information, or the operation data.

3. The machining load determination system according to claim 1, wherein
the actual load information includes energy that occurs in the movable unit at a time of machining the machining target object, and
the virtual load information includes energy that occurs in the virtual movable unit at a time of machining the virtual machining target object.

4. The machining load determination system according to claim 1, wherein
the actual load information is contact information indicating whether or not the tool and the machining target object are in contact with each other, and
the virtual load information is contact information indicating whether or not the virtual tool and the virtual machining target object are in contact with each other.

5. The machining load determination system according to claim 1, wherein the load information determination unit makes the determination in real time while the actual machining unit is operating.

6. The machining load determination system according to claim 1, wherein in a case where the load information determination unit determines that there is a difference between the virtual load information and the actual load information, the actual machining unit performs at least any of restriction of output for causing the movable unit to operate, a preset retraction operation of the movable unit, or immediate decelerating and stopping of operation of the movable unit.

7. The machining load determination system according to claim 1, wherein
the simulation unit performs the machining simulation based on the operation data, the operation data including prerequisites about the virtual tool, the virtual machining target object, and the virtual movable unit, and
in a case where the load information determination unit determines that there is a difference between the virtual load information and the actual load information, the simulation unit identifies, in the operation data, a process where the difference between the virtual load information and the actual load information exists based on the comparison position identification data, and changes the prerequisites for the machining simulation.

8. The machining load determination system according to claim 1, wherein
the actual load information is contact information indicating whether or not the tool and the machining target object are in contact with each other,
the virtual load information is contact information indicating whether or not the virtual tool and the virtual machining target object are in contact with each other, the comparison position identification data for the actual load information includes position information about the movable unit,
the comparison position identification data for the virtual load information includes position information about the virtual movable unit,
the simulation unit performs the machining simulation based on the operation data that includes prerequisites about the virtual tool, the virtual machining target object, and the virtual movable unit, and
in a case where the load information determination unit determines that there is a difference between the virtual load information and the actual load information, the simulation unit calculates a difference between machine coordinates at which the tool and the machining target object in the actual machining unit have come into contact with each other and machine coordinates at which the virtual tool and the virtual machining target object in the simulation unit have come into contact with each other is calculated, and
the simulation unit changes the prerequisites for the virtual tool, with the difference as a correction amount for the virtual tool.

9. The machining load determination system according to to claim 1, wherein the simulation unit performs the machining simulation before the actual machining unit performs operation based on the operation data, and calculates the comparison position identification data and the virtual load information.

10. The machining load determination system according to claim 2, wherein the virtual load acquisition unit writes at least any of the comparison position identification data or the virtual load information in the operation data.

11. The machining load determination system according to claim 1, comprising a display unit that displays comparison position identification data for which the load information determination unit has determined that there is a difference between the virtual load information and the actual load information, in a display manner varying according to the difference.

12. The machining load determination system according to claim 1, wherein the load information determination unit extracts and compares only a part of the virtual load information with only a part of the actual load information corresponding to a certain particular section in the comparison position identification data.
